(19) United States
(12) Patent Application Publication
(10) Pub. No.: US 2025/0365942 A1
(43) Pub. Date: Nov. 27, 2025

(54) SEMICONDUCTOR MEMORY DEVICES

(71) Applicant: Samsung Electronics Co., Ltd., Suwon-si (KR)

(72) Inventors: Yujin KIM, Suwon-si (KR); Hyeoncheol KIM, Suwon-si (KR); Bowon YOO, Suwon-si (KR); Seunguk HAN, Suwon-si (KR); Jinwoo HAN, Suwon-si (KR)

(73) Assignee: Samsung Electronics Co., Ltd., Suwon-si (KR)

(21) Appl. No.: 19/018,660

(22) Filed: Jan. 13, 2025

(30) Foreign Application Priority Data
May 22, 2024 (KR) 10-2024-0066594

(51) Int. Cl. H10B 12/00

(52) U.S. Cl. CPC H10B 12/488; H10B 12/315; H10B 12/482; H10B 12/50

(57) ABSTRACT

A semiconductor memory device includes a plurality of semiconductor patterns extending in a first horizontal direction on a substrate and apart from each other in a vertical direction and a second horizontal direction crossing the first horizontal direction, the plurality of semiconductor patterns each including a first part having a first width in the second horizontal direction and a second part having a second width in the second horizontal direction, the second width being less than the first width, a plurality of word lines extending in the second horizontal direction, the plurality of word lines each surrounding the first part of each of the plurality of semiconductor patterns, and a plurality of cell capacitors each surrounding the second part of each of the plurality of semiconductor patterns.

### CROSS-REFERENCE TO RELATED APPLICATION

This application is based on and claims priority under 35 U.S.C. § 119 to Korean Patent Application No. 10-2024-0066594, filed on May 22, 2024, in the Korean Intellectual Property Office, the disclosure of which is incorporated by reference herein in its entirety.

### BACKGROUND

The inventive concepts relate to semiconductor memory devices, and more particularly, to three-dimensional (3D) semiconductor memory devices.

With the demand for compact and multifunctionalized high-performance electronic products, high-capacity semiconductor memory devices are required. To provide high-capacity semiconductor memory devices, an increase in the integration density is demanded. 3D semiconductor memory devices for increasing memory capacity by stacking memory cells on a substrate in the vertical direction have been proposed.

### SUMMARY

The inventive concepts provide three-dimensional semiconductor memory devices having increased memory capacity.

According to an aspect of the inventive concepts, there is provided a semiconductor memory device including a plurality of semiconductor patterns extending in a first horizontal direction on a substrate, the plurality of semiconductor patterns spaced apart from each other in a vertical direction and a second horizontal direction crossing the first horizontal direction, the plurality of semiconductor patterns each including a first part having a first width in the second horizontal direction and a second part having a second width in the second horizontal direction, the second width being less than the first width; a plurality of word lines extending in the second horizontal direction, the plurality of word lines each surrounding the first part of a corresponding semiconductor pattern of the plurality of semiconductor patterns; and a plurality of cell capacitors each surrounding the second part of a corresponding semiconductor pattern of the plurality of semiconductor patterns.

According to another aspect of the inventive concepts, there is provided a semiconductor memory device including a plurality of semiconductor patterns extending in a first horizontal direction on a substrate, the plurality of semiconductor patterns spaced apart from each other in a vertical direction and a second horizontal direction crossing the first horizontal direction, the plurality of semiconductor patterns each including a first part having a first width in the second horizontal direction and a second part having a second width in the second horizontal direction, the second width being less than the first width; a plurality of word lines extending in the second horizontal direction, the plurality of word lines each surrounding the first part of a corresponding semiconductor pattern of the plurality of semiconductor patterns; a plurality of cell capacitors each surrounding the second part of a corresponding semiconductor pattern of the plurality of semiconductor patterns, and a plate electrode extending in the vertical direction on the substrate and connected to the plurality of cell capacitors, wherein the second width of the second part of each of the plurality of semiconductor patterns decreases towards the plate electrode.

According to a further aspect of the inventive concepts, there is provided a semiconductor memory device including a peripheral circuit region at a first vertical level; and a cell array region at a second vertical level different from the first vertical level, wherein the cell array region includes a plurality of semiconductor patterns extending in a first horizontal direction on a substrate, the plurality of semiconductor patterns spaced apart from each other in a vertical direction and a second horizontal direction crossing the first horizontal direction, the plurality of semiconductor patterns each including a first part having a first width in the second horizontal direction and a second part having a second width in the second horizontal direction, the second width being less than the first width; a plurality of word lines extending in the second horizontal direction, the plurality of word lines each surrounding the first part of a corresponding semiconductor pattern of the plurality of semiconductor patterns; a plurality of cell capacitors each surrounding the second part of a corresponding semiconductor pattern of the plurality of semiconductor patterns; a plurality of intermediate conductive layers, each of the plurality of intermediate conductive layers on a top surface of and a bottom surface of the second part of a corresponding semiconductor pattern of the plurality of semiconductor patterns, the plurality of intermediate conductive layers comprising a metal silicide; a plate electrode extending in the vertical direction on the substrate and connected to the plurality of cell capacitors; and a plurality of bit lines extending in the vertical direction, each of the plurality of bit lines connected to an end of the first part of each of the plurality of semiconductor patterns.

### BRIEF DESCRIPTION OF THE DRAWINGS

Embodiments will be more clearly understood from the following detailed description taken in conjunction with the accompanying drawings in which:

FIG. 1 is a schematic block diagram of a semiconductor memory device according to embodiments;

FIG. 2 is a circuit diagram of a cell array region in FIG. 1;

FIG. 3 is a schematic layout diagram of the cell array region in FIG. 1;

FIG. 4 is an enlarged layout diagram of a region A1 in FIG. 3;

FIG. 5 is a cross-sectional view taken along line A-A′ in FIG. 4;

FIG. 6 is a cross-sectional view taken along line B-B′ in FIG. 4;

FIG. 7 is a cross-sectional view taken along line C-C′ in FIG. 4;

FIG. 8 is a cross-sectional view taken along line D-D′ in FIG. 4;

FIG. 9 is an enlarged layout diagram of a region EN1 in FIG. 4;

FIG. 10 is an enlarged layout diagram of a region EN2 in FIG. 5;

FIG. 11 is an enlarged layout diagram of a region EN3 in FIG. 6;

FIG. 12 is an enlarged layout diagram of a region EN4 in FIG. 7;

FIG. 13 is a cross-sectional view of a semiconductor memory device according to embodiments;

FIG. 14 is a plan view of a semiconductor memory device according to embodiments;

FIG. 15 is a cross-sectional view of a semiconductor memory device according to embodiments; and

FIGS. 16A, 16B, 17A, 17B, 18A, 18B, 18C, 19A, 19B, 19C, 20A, 20B, 20C, 20D, 21A, 21B, 21C, 22A, 22B, 22C, 23A, 23B, 23C, 24A, 24B, 24C, 24D, 25A, 25B, and 25C are schematic diagrams illustrating a method of manufacturing a semiconductor memory device, wherein FIGS. 16A, 17A, 18A, 19A, 20A, 21A, 22A, 23A, 24A, and 25A are plan views of sequential stages in the method, FIGS. 16B, 17B, 18B, 19B, 20B, 21B, 22B, 23B, 24B, and 25B are cross-sectionals views taken along line A-A in FIGS. 16A, 17A, 18A, 19A, 20A, 21A, 22A, 23A, 24A, and 25A, respectively, FIGS. 18C, 19C, and 22C are cross-sectional views taken along line B-B in FIGS. 18A, 19A, and 22A, respectively, FIGS. 20C, 21C, 24C, and 25C are cross-sectional views taken along line C-C in FIGS. 20A, 21A, 24A, and 25A, respectively, FIG. 23C is a cross-sectional view taken along line D-D in FIG. 23A, and FIGS. 20D and 24D are enlarged views of a region EN1 in FIGS. 20A and 24A, respectively.

### DETAILED DESCRIPTION OF THE EMBODIMENTS

Hereinafter, embodiments of the inventive concepts are described in detail with reference to the accompanying drawings. However, various alterations and modifications may be made to the embodiments and thus, the scope of the disclosure is not limited or restricted to the embodiments. The equivalents should be understood to include all changes, equivalents, and replacements within the idea and the technical scope of the disclosure.

Like reference numerals in the drawings denote like components, and therefore repeat descriptions thereof will be omitted. Some sizes of components in the drawings may be exaggerated for convenience of explanation. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will also be understood that such spatially relative terms, such as “above,” “top,” “vertical,” “lateral,” etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

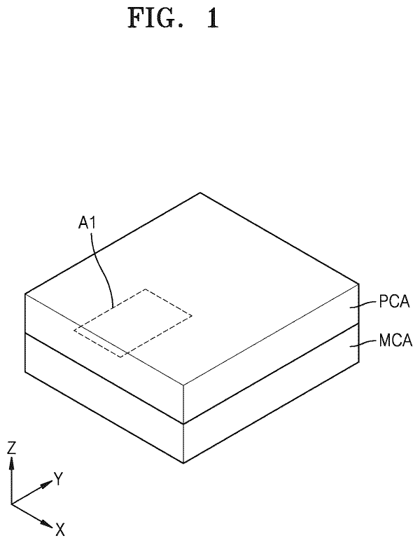

FIG. 1 is a schematic block diagram of a semiconductor memory device according to embodiments.

Referring to FIG. 1, a semiconductor memory device 100 may include a cell array region MCA and a peripheral circuit region PCA vertically overlapping each other. For example, the peripheral circuit region PCA may be at a vertical level that is higher than the vertical level of the cell array region MCA.

In some embodiments, the cell array region MCA may correspond to a memory cell region of a dynamic random access memory (DRAM) device, and the peripheral circuit region PCA may correspond to a core region or a peripheral circuit region of the DRAM device. For example, the peripheral circuit region PCA may include a peripheral circuit transistor, which transmits a signal and/or power to a memory cell array in the cell array region MCA. In some embodiments, a peripheral circuit transistor may form various circuits, such as a command decoder, a control logic, an address buffer, a row decoder, a column decoder, a sense amplifier, and/or a data input/output circuit.

Although it is illustrated in FIG. 1 that the peripheral circuit region PCA is arranged at a higher vertical level than the cell array region MCA (e.g., the peripheral circuit region PCA is arranged on the cell array region MCA), the semiconductor memory device 100 may be turned over such that the cell array region MCA is located at a higher vertical level than the peripheral circuit region PCA.

In some embodiments, each of the peripheral circuit region PCA and the cell array region MCA may be formed on an individual wafer and then attached to each other, e.g., using a bonding pad. In some embodiments, the peripheral circuit region PCA may be formed on a peripheral circuit wafer, and then, the cell array region MCA may be formed on the peripheral circuit region PCA.

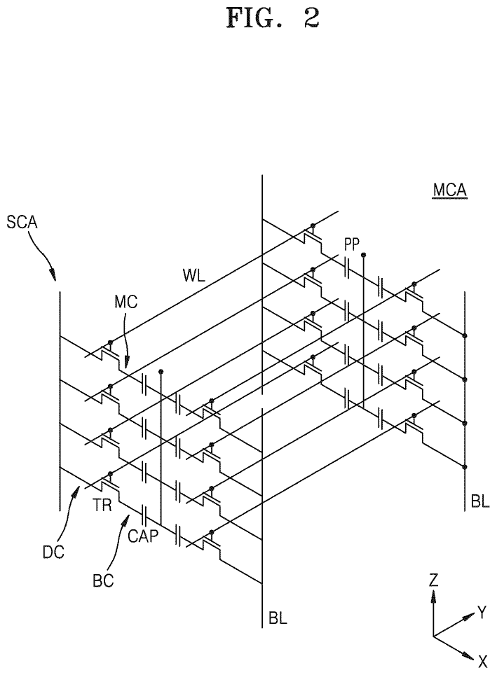

FIG. 2 is a circuit diagram of the cell array region MCA in FIG. 1.

Referring to FIG. 2, the cell array region MCA may include a plurality of sub cell arrays SCA. The sub cell arrays SCA may be apart from each other in a second horizontal direction Y.

Each of the sub cell arrays SCA may include a plurality of bit lines BL, a plurality of word lines WL, and a plurality of memory cells MC. Each of the memory cells MC may include one cell transistor TR and one cell capacitor CAP connected to the cell transistor TR. Each of the memory cells MC may have a 1 transistor-1 capacitor (1TIC) structure.

The word lines WL may extend in the second horizontal direction Y and may be spaced apart from one another in a first horizontal direction X and a vertical direction Z. The bit lines BL may extend in the vertical direction Z and may be spaced apart from one another in the first horizontal direction X and the second horizontal direction Y. One cell transistor TR may be arranged between one word line WL and one bit line BL.

The gate of the cell transistor TR may be connected to the word line WL, and the source of the cell transistor TR may be connected to the bit line BL through a first contact DC. The cell transistor TR may be connected to the cell capacitor CAP through a second contact BC. The drain of the cell transistor TR may be connected to a first electrode of the cell capacitor CAP through the second contact BC, and a second electrode of the cell capacitor CAP may be connected to a plate electrode PP.

In one sub cell array SCA, a plurality of cell transistors TR may overlap with each other in the vertical direction Z. In one sub cell array SCA, a plurality of cell capacitors CAP may overlap with each other in the vertical direction Z. One cell transistor TR and one cell capacitor CAP may be arranged in parallel at the same vertical level. A plurality of memory cells MC, each including one cell transistor TR and one cell capacitor CAP, may be stacked in the vertical direction Z. The storage capacity of the sub cell array SCA may vary with the number of memory cells MC (or cell capacitors CAP) stacked in the vertical direction Z.

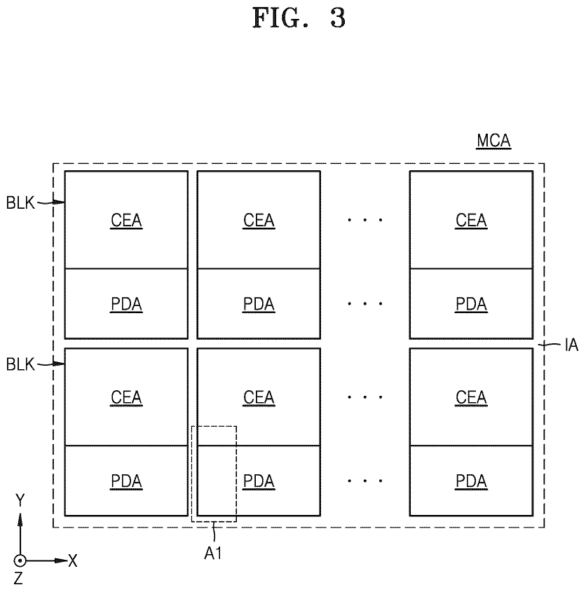

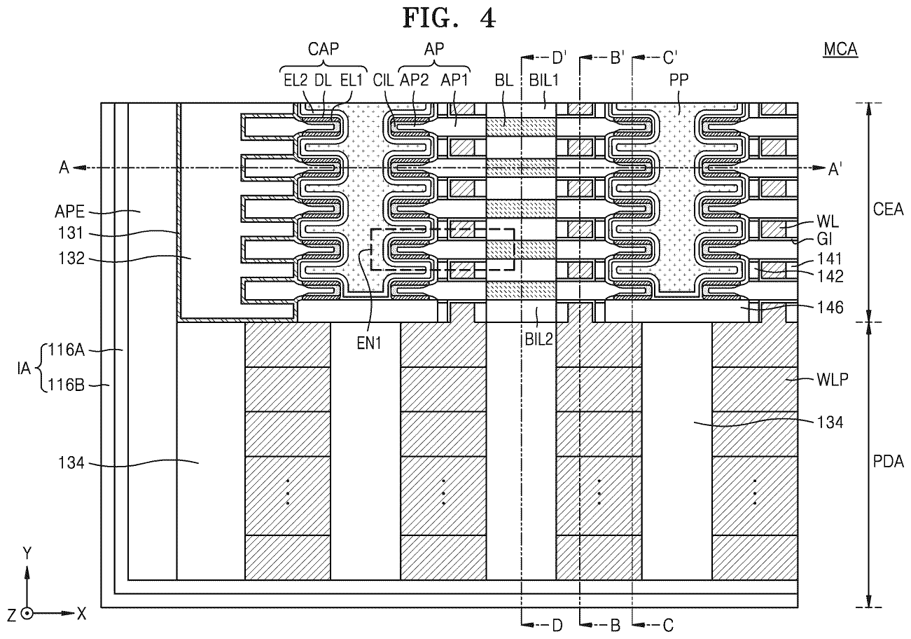

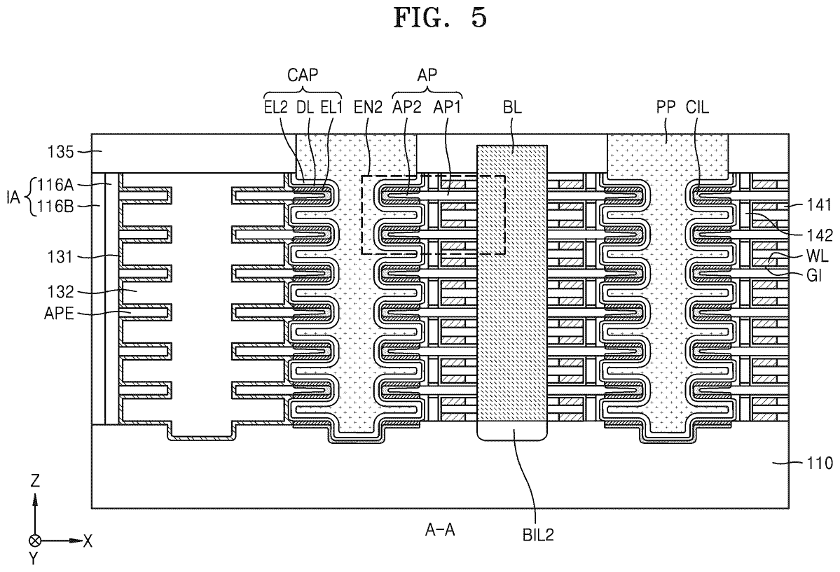

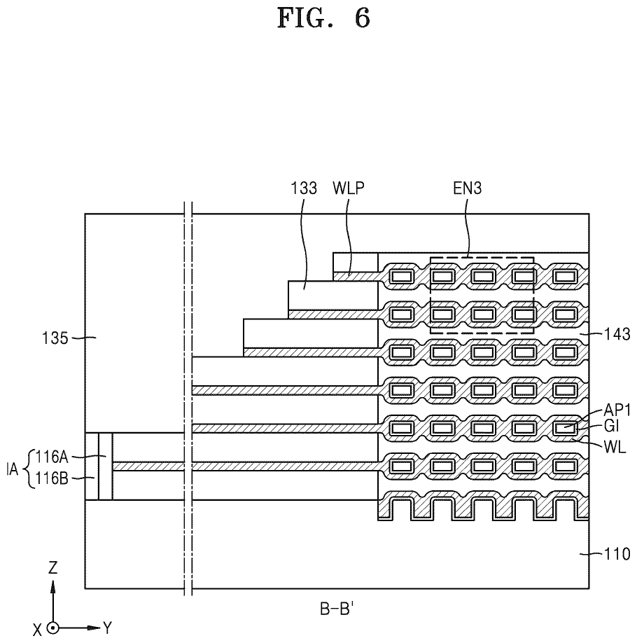

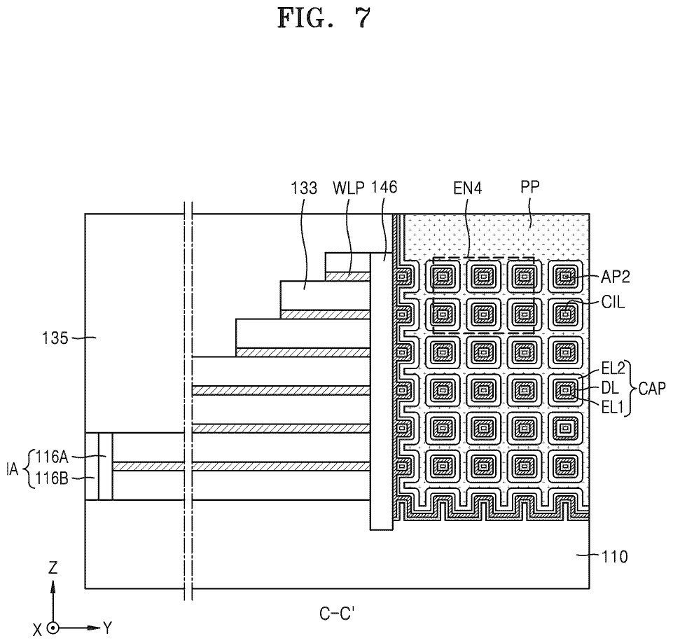

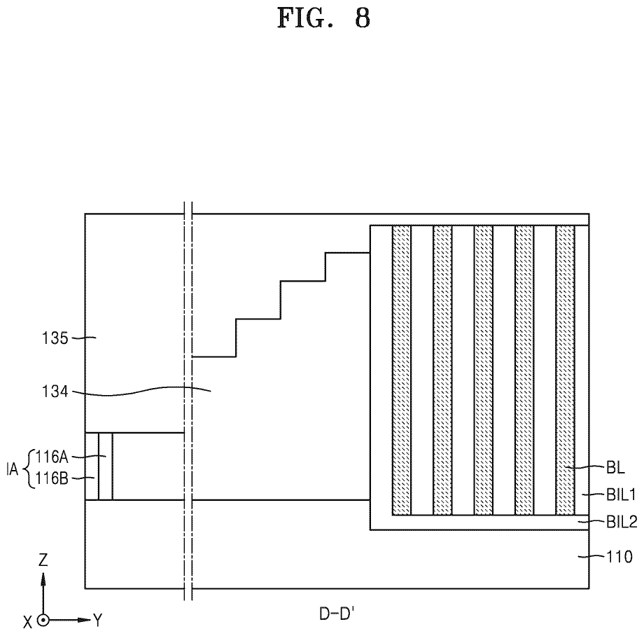

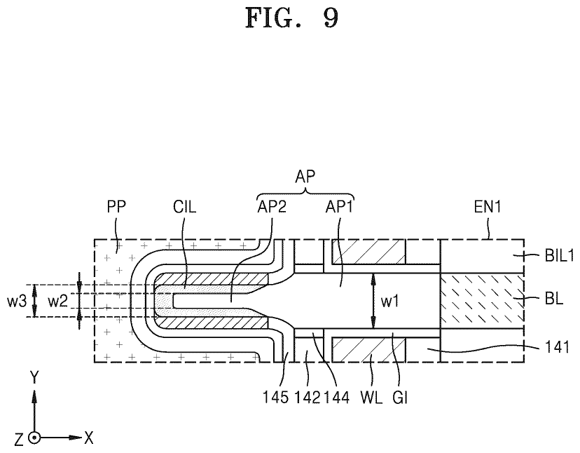

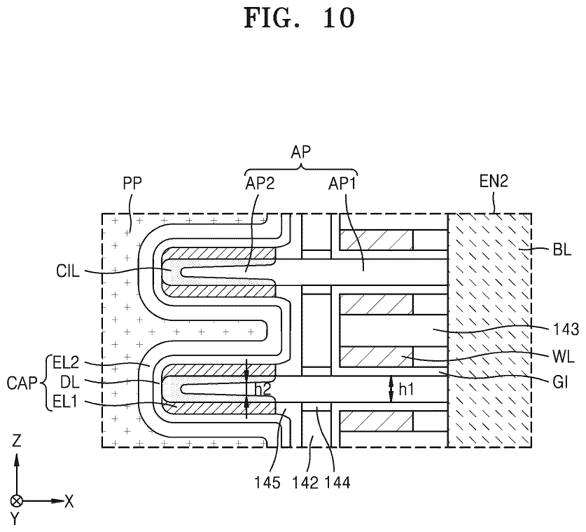

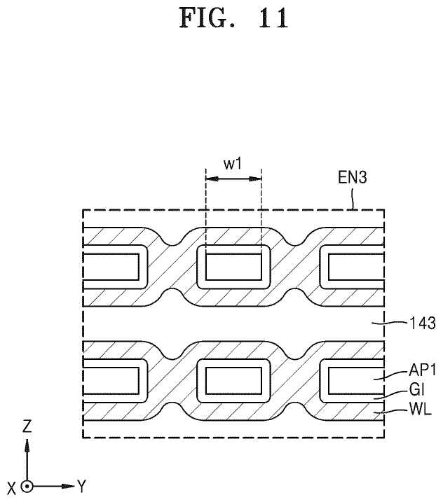

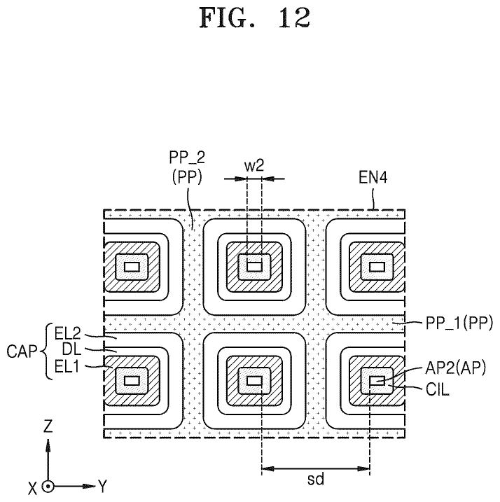

FIG. 3 is a schematic layout diagram of the cell array region MCA in FIG. 1. FIG. 4 is an enlarged layout diagram of a region A1 in FIG. 3. FIG. 5 is a cross-sectional view taken along line A-A′ in FIG. 4. FIG. 6 is a cross-sectional view taken along line B-B′ in FIG. 4. FIG. 7 is a cross-sectional view taken along line C-C′ in FIG. 4. FIG. 8 is a cross-sectional view taken along line D-D′ in FIG. 4. FIG. 9 is an enlarged layout diagram of a region EN1 in FIG. 4. FIG. 10 is an enlarged layout diagram of a region EN2 in FIG. 5. FIG. 11 is an enlarged layout diagram of a region EN3 in FIG. 6. FIG. 12 is an enlarged layout diagram of a region EN4 in FIG. 7.

Referring to FIGS. 3 to 12, the cell array region MCA may include a plurality of cell blocks BLK. Each of the cell blocks BLK may include a cell block region CEA and a connection region PDA. One or more cell transistors TR and one or more cell capacitors CAP, which have been described with reference to FIG. 2, may be arranged in the cell block region CEA. A word line pad WLP for electrical connection to a word line WL of the cell block region CEA may be arranged in the connection region PDA.

As shown in FIG. 3, the connection region PDA may be arranged at one side of the cell block region CEA, and a device isolation region IA may be arranged between two adjacent cell block regions CEA. In some embodiments, unlike FIG. 3, the connection region PDA may be arranged at each of opposite sides of the cell block region CEA.

In some embodiments, the connection region PDA and the cell block region CEA may be arranged on a first substrate 110. The first substrate 110 may include a semiconductor material, such at least one of Si, Ge, or SiGe. In some embodiments, the first substrate 110 may include a silicon-on-insulator (SOI) substrate and/or a germanium-on-insulator (GeOI) substrate.

In the cell array region MCA, a plurality of semiconductor patterns AP may extend in the first horizontal direction X on the first substrate 110 and may be spaced apart from one another in the second horizontal direction Y and the vertical direction Z.

In some embodiments, the semiconductor patterns AP may include an undoped semiconductor material and/or a doped semiconductor material. In some embodiments, the semiconductor patterns AP may include polysilicon, an amorphous metal oxide, a polycrystalline metal oxide, a combination of amorphous metal oxide and polycrystalline metal oxide, a two-dimensional (2D) material semiconductor, etc. For example, the semiconductor patterns AP may include at least one of In—Ga oxide (IGO), In—Zn oxide (IZO), In—Ga—Zn oxide (IGZO), and/or the like. For example, the 2D material semiconductor may include MoS₂, WSe₂, doped graphene, semiconductive carbon nanotube, and/or a combination thereof.

In some embodiments, each of the semiconductor patterns AP may include a first part AP1 and a second part AP2. For example, each of the semiconductor patterns AP may be relatively long in the first horizontal direction X and may have a different width in the second horizontal direction Y and a different height in the vertical direction Z. The first part AP1 of each semiconductor pattern AP may be connected to a bit line BL, and the second part AP2 of a semiconductor pattern AP may be adjacent to the cell capacitor CAP.

In some embodiments, the first part AP1 of the semiconductor pattern AP may have a first width w1 in the second horizontal direction Y. The second part AP2 of the semiconductor pattern AP may have a second width w2 in the second horizontal direction Y, and the second width w2 may be less than the first width w1. In some embodiments, the first part AP1 of the semiconductor pattern AP may have a first height h1 in the vertical direction Z. The second part AP2 of the semiconductor pattern AP may have a second height h2 in the vertical direction Z, and the second height h2 may be less than the first height h1.

In some embodiments, the second part AP2 of the semiconductor pattern AP may have a tapered shape. For example, the width and the height of the second part AP2 of the semiconductor pattern AP may decrease toward the cell capacitor CAP.

In some embodiments, the first part AP1 of the semiconductor pattern AP may be formed by a patterning process using a first mask pattern, and the second part AP2 of the semiconductor pattern AP may be formed by a patterning process using a second mask pattern. Accordingly, the width of the second part AP2 of the semiconductor pattern AP may be less than the width of the first part AP1 of the semiconductor pattern AP.

In some embodiments, the first part AP1 of the semiconductor pattern AP may function as a channel region and a drain region of a transistor and the first contact DC (in FIG. 2), and the second part AP2 of the semiconductor pattern AP may function as a source region of the transistor and the second contact BC (in FIG. 2).

A plurality of word lines WL may be apart from each other in the vertical direction Z and may extend in the second horizontal direction Y. Each of the word lines WL may be arranged on the top surface, bottom surface, and sidewalls of first parts AP1 of a plurality of semiconductor patterns AP. One of the word lines WL may extend in the second horizontal direction Y such that the word line WL surrounds a plurality of semiconductor patterns AP, which are apart from each other in the second horizontal direction Y. Two word lines WL spaced apart from each other in the vertical direction Z among the plurality of word lines WL may overlap each other in the vertical direction Z.

In some embodiments, the word lines WL may include a conductive material (e.g., a material with no band gap). For example, the word lines WL may include at least one of a doped semiconductor material (e.g., doped silicon and doped germanium), a conductive metal nitride (e.g., titanium nitride and tantalum nitride), a metal (e.g., tungsten, titanium, and tantalum), metal-semiconductor compounds (e.g., tungsten silicide, cobalt silicide, and titanium silicide), and/or the like.

In some embodiments, a gate insulating layer GI may be between a word line WL and a semiconductor pattern AP. The gate insulating layer GI may include at least one of a ferroelectric material and a high-k dielectric material having a higher dielectric constant than silicon oxide. In some embodiments, the gate insulating layer GI may include an insulator, such as at least one of hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicon oxide (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrBiTaO), bismuth iron oxide (BiFeO), strontium titanium oxide (SrTiO), yttrium oxide (YO), aluminum oxide (AlO), lead scandium tantalum oxide (PbScTaO), and/or the like.

A portion of the first part AP1 of each semiconductor pattern AP may be surrounded by a first spacer 141. For example, the first spacer 141 may be disposed on a first end portion (e.g., adjacent to a bit line BL) of each of the word lines WL in the first horizontal direction X. A second spacer 142 may be disposed on a second end portion (e.g., adjacent to the cell capacitor CAP) of each word line WL in the first horizontal direction X. A third spacer 143 may be arranged between two adjacent word lines WL in the vertical direction Z.

In some embodiments, the first spacer 141 and the second spacer 142 may include silicon nitride or silicon oxynitride, and the third spacer 143 may include silicon oxide.

Although it is illustrated in FIG. 4 that the gate insulating layer GI is between a word line WL and the first part AP1 of a semiconductor pattern AP, between the first spacer 141 and the first part AP1 of the semiconductor pattern AP, and between the second spacer 142 and the word line WL, the gate insulating layer GI may be only between the word line WL and the first part AP1 of the semiconductor pattern AP.

In some embodiments, a first insulating liner 144 may be between the first part AP1 of the semiconductor pattern AP and the second spacer 142, and a second insulating liner 145 may be disposed on a portion of a sidewall of the second part AP2 of the semiconductor pattern AP and a sidewall of the second spacer 142. In some embodiments, the first insulating liner 144 and the second insulating liner 145 may include silicon oxide.

A plurality of bit lines BL may extend in the vertical direction Z on the first substrate 110 and may be spaced apart from each other in the second horizontal direction Y. The bit lines BL may include a conductive material (e.g., a material with no band gap). For example, the bit lines BL may include a doped semiconductor material, conductive metal nitride, metal, or a metal-semiconductor compound. A first bit line isolation insulating layer BIL1 may be between two bit lines BL adjacent to each other in the second horizontal direction Y and may extend in the vertical direction Z. A second bit line isolation insulating layer BIL2 may be between the bit lines BL and the first substrate 110.

In some embodiments, as shown in FIG. 4, one bit line BL may be between two semiconductor patterns AP spaced apart from each other in the first horizontal direction X. Two transistors formed by these two semiconductor patterns AP may share one bit line BL.

In some embodiments, an ohmic metal layer (not illustrated) including a metal silicide may be further arranged between the first part AP1 of the semiconductor pattern AP and the bit line BL.

An intermediate conductive layer CIL may be disposed on the top surface, bottom surface, and sidewall of the second part AP2 of the semiconductor pattern AP. In some embodiments, the intermediate conductive layer CIL may include a metal silicide, such as cobalt silicide, nickel silicide, or tungsten silicide. The intermediate conductive layer CIL may surround the second part AP2 of the semiconductor pattern AP. The intermediate conductive layer CIL may have a third width w3 in the second horizontal direction Y. For example, the third width w3 may be defined by a first sidewall and a second sidewall, which face (or are opposite to) each other in the second horizontal direction Y. The third width w3 may be less than the first width w1 of the first part AP1 of the semiconductor pattern AP and greater than the second width w2 of the second part AP2 of the semiconductor pattern AP.

The cell capacitor CAP may include a first electrode EL1, a capacitor dielectric layer DL, and a second electrode EL2. The first electrode EL1 may be arranged on the top surface, the bottom surface, and the sidewall of the intermediate conductive layer CIL. For example, as shown in FIG. 10, the intermediate conductive layer CIL may be between the first electrode EL1 and the second part AP2 of the semiconductor pattern AP. The first electrode EL1 may have a cylindrical shape extending in the first horizontal direction X. An end of the first electrode EL1 in the first horizontal direction X may be in contact with the second insulating liner 145.

The capacitor dielectric layer DL may be arranged on the first electrode EL1. For example, the capacitor dielectric layer DL may be conformally arranged on the top surface, the bottom surface, and the sidewall of the first electrode EL1. As shown in FIG. 5, a portion of the sidewall of the intermediate conductive layer CIL may not be covered with the first electrode EL1, and at least a portion of the capacitor dielectric layer DL may be in contact with the intermediate conductive layer CIL. In some embodiments, unlike FIG. 5, the whole sidewall of the intermediate conductive layer CIL may be covered with the first electrode EL1. In this case, the capacitor dielectric layer DL may not be in direct contact with the intermediate conductive layer CIL.

In some embodiments, the capacitor dielectric layer DL may include at least one of a ferroelectric material and/or a high-k dielectric material having a higher dielectric constant than silicon oxide. In some embodiments, the capacitor dielectric layer DL may include at least one of HfO, HfSiO, HfON, HfSiON, LaO, LaAlO, ZrO, ZrSiO, ZrON, ZrSiON, TaO, TiO, BaSrTiO, BaTiO, PbZrTiO, SrBiTaO, BiFeO, SrTiO, YO, AlO, PbScTaO, and/or the like.

The second electrode EL2 may be arranged on the capacitor dielectric layer DL. The second electrode EL2 may be conformally arranged on the top surface, the bottom surface, and the sidewall of the capacitor dielectric layer DL. For example, the capacitor dielectric layer DL may be between the first electrode EL1 and the second electrode EL2. The second electrode EL2 may include a conductive material.

For example, in some embodiments, the first electrode EL1 and the second electrode EL2 may include each a doped semiconductor material, conductive a metal nitride such as titanium nitride, tantalum nitride, niobium nitride, or tungsten nitride, a metal such as ruthenium, iridium, titanium, or tantalum, or a conductive metal oxide such as iridium oxide or niobium oxide. The conductive material of the first electrode EL1 and the second electrode EL2 may be the same and/or different.

The plate electrode PP may be arranged at one side of the cell capacitor CAP and may extend in the vertical direction Z and the second horizontal direction Y. The second electrode EL2 of the cell capacitor CAP may be electrically connected to the plate electrode PP. For example, the plate electrode PP may be connected in common to a plurality of second electrodes EL2, which are spaced apart from each other in the vertical direction Z, and a plurality of second electrodes EL2, which are spaced apart from each other in the second horizontal direction Y.

In some embodiments, at least a portion (e.g., a first protrusion PP_1 of the plate electrode PP in FIG. 12) may be between two cell capacitors CAP adjacent to each other in the vertical direction Z, or at least a portion (e.g., a second protrusion PP_2 of the plate electrode PP in FIG. 12) may be between two cell capacitors CAP adjacent to each other in the second horizontal direction Y.

In some embodiments, the second part AP2 of the semiconductor pattern AP may have a relatively small width. For example, the second width w2 (that is less than the first width w1 of the first part AP1 of the semiconductor pattern AP), and respective second parts AP2 of two adjacent semiconductor patterns AP may be apart from each other by a relatively great distance “sd” in the second horizontal direction Y. Accordingly, the gap between two adjacent cell capacitors CAP may be secured relatively large, and at least a portion (e.g., the second protrusion PP_2) of the plate electrode PP may be arranged between two adjacent cell capacitors CAP.

A buried insulating layer 146 may be arranged at the edge of the cell block region CEA. The first electrode EL1, the capacitor dielectric layer DL, and the second electrode EL2 of a cell capacitor CAP may be partially arranged on the sidewall of the buried insulating layer 146.

A plurality of semiconductor edge patterns APE may be arranged at the edge of the cell block region CEA, which is adjacent to the device isolation region IA. The semiconductor edge patterns APE may be apart from each other in the vertical direction Z and may be at the same vertical levels as the plurality of semiconductor patterns AP, respectively. An edge liner 131 may conformally surround the semiconductor edge patterns APE. An edge burying layer 132 may be arranged on the edge liner 131 and may fill the space between the semiconductor edge patterns APE.

Word line pads WLP may be arranged in the connection region PDA and respectively connected to a plurality of word lines WL. In some embodiments, the word lines pads WLP may be formed in a stepped pattern in the second horizontal direction Y. For example, a word line pad WLP connected to one word line WL at a first vertical level may not vertically overlap but may be adjacent in the second horizontal direction Y to another word line pad WLP connected to another word line WL that is at a second vertical level different from the first vertical level (e.g., another word line WL below one word line WL).

Pad insulating layers 133 may be respectively disposed on the word line pads WLP. A word line isolation insulating layer 134 may be between two word line pads WLP adjacent to each other in the first horizontal direction X. The word line isolation insulating layer 134 may have a stair shape. The top surface of each of the steps of the word line isolation insulating layer 134 may be coplanar with the top surface of each of the pad insulating layers 133. A cover insulating layer 135 may be arranged to cover the pad insulating layers 133, the word line pads WLP, and the word line isolation insulating layer 134.

The device isolation region IA may be around the cell block region CEA and the connection region PDA and may include a first device isolation layer 116A and a second device isolation layer 116B. In some embodiments, the first device isolation layer 116A may include silicon nitride and the second device isolation layer 116B may include silicon oxide.

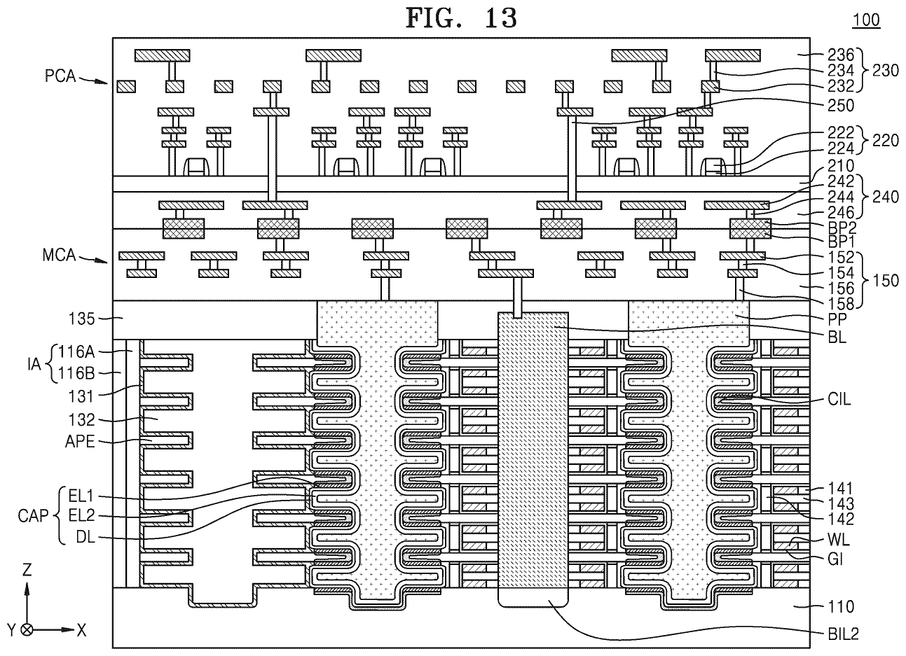

FIG. 13 is a cross-sectional view of a semiconductor memory device 100 according to embodiments FIG. 13 illustrates an embodiment, in which a peripheral circuit region PCA is attached to a cell array region MCA by bonding pads (e.g., BP1 and BP2).

Referring to FIG. 13, an upper wiring structure 150 may be arranged in an upper portion of the cell array region MCA. The upper wiring structure 150 may include a wiring layer 152, a via 154, and an insulating layer 156. The upper wiring structure 150 may further include a contact 158, which is electrically connected to a bit line BL, a word line WL, and a plate electrode PP. A first bonding pad BP1 may be arranged in the upper wiring structure 150 to be on the same plane as the topmost surface of the insulating layer 156.

The peripheral circuit region PCA may include a second substrate 210, a peripheral circuit transistor 220 on the substrate 210, a front wiring structure 230 on the substrate 210, and a back wiring structure 240 on the bottom surface of the substrate 210. The front wiring structure 230 may cover the peripheral circuit transistor 220. The front wiring structure 230 may include a wiring layer 232, a via 234, and an insulating layer 236. The back wiring structure 240 may include a wiring layer 242, a via 244, and an insulating layer 246.

The back wiring structure 240 may further include a second bonding pad BP2 on the same plane as the bottom surface of the insulating layer 246. When the first bonding pad BP1 is connected to the second bonding pad BP2, the cell array region MCA may be bonded to the peripheral circuit region PCA. In some embodiments, the cell array region MCA and the peripheral circuit region PCA may be attached to each other by a copper-oxide hybrid bonding method. In some embodiments, the first bonding pad BP1 and the second bonding pad BP2 may include copper or a copper alloy. The interface between the insulating layer 156 of the upper wiring structure 150 and the insulating layer 246 of the back wiring structure 240 may evenly extend and may be coplanar with the interface between the first bonding pad BP1 and the second bonding pad BP2.

In some embodiments, the peripheral circuit transistor 220 may include a gate electrode 222 and a gate insulating layer 224, which are arranged in an active region of the substrate 210. In some embodiments, the peripheral circuit transistor 220 may include sense amplifiers, which may be electrically connected to bit lines BL in the cell array region MCA. In some embodiments, the peripheral circuit transistor 220 may include sub word line drivers, which may be electrically connected to word lines WL in the cell array region MCA.

In some embodiments, the peripheral circuit region PCA may further include a through via 250 that passes through the second substrate 210. The wiring layer 232 of the front wiring structure 230 may be electrically connected to the wiring layer 242 of the back wiring structure 240 by the through via 250. The wiring layer 242 of the back wiring structure 240 may be electrically connected to the wiring layer 152 of the upper wiring structure 150 through the second bonding pad BP2 and the first bonding pad BP1.

In general, to form a three-dimensional (3D) DRAM device, a semiconductor pattern extending in one direction is formed, a word line surrounding a portion of the semiconductor pattern is formed, and a cell capacitor surrounding the other portion of the semiconductor pattern is formed. However, because the cell capacitor is formed by sequentially forming a lower electrode, a capacitor dielectric layer, and an upper electrode, a process defect may occur such that the capacitor dielectric layer and/or the upper electrode may not completely fit into the narrow space between semiconductor patterns.

However, according to the semiconductor memory device 100 described with reference to FIGS. 1 to 13, a plurality of semiconductor patterns AP each may include the first part AP1 that is relatively wide and the second part AP2 that is relatively narrow. The first part AP1 of each of the semiconductor patterns AP may be covered with a word line WL and the second part AP2 of each semiconductor pattern AP may be covered with a cell capacitor CAP. Because the second part AP2 of each of the semiconductor patterns AP is relatively narrow, a process defect in which the first electrode EL1, the capacitor dielectric layer DL, and the second electrode EL2 of the capacitor CAP do not fit into the space between two adjacent second parts AP2 may be prevented. Because the first part AP1 of each semiconductor pattern AP is relatively wide, the performance of a transistor may be optimized.

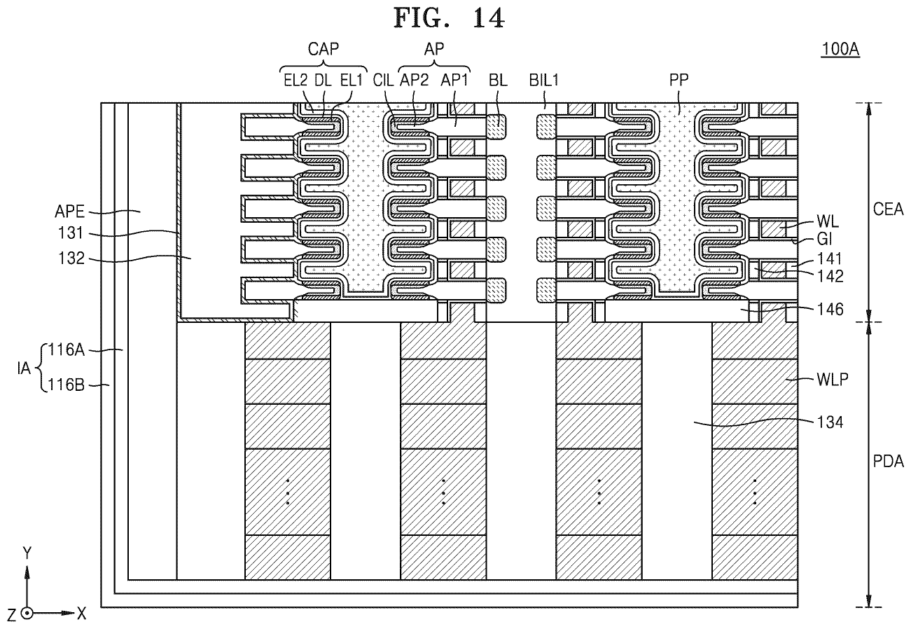

FIG. 14 is a plan view of a semiconductor memory device 100A according to embodiments.

Referring to FIG. 14, two bit lines BL may be apart from each other and arranged between two semiconductor patterns AP, which are apart from each other in the first horizontal direction X. For example, one bit line BL may be connected to one semiconductor pattern AP, and another bit line BL may be connected to another semiconductor pattern AP. The sidewall of a bit line BL may be covered with the first bit line isolation insulating layer BIL1.

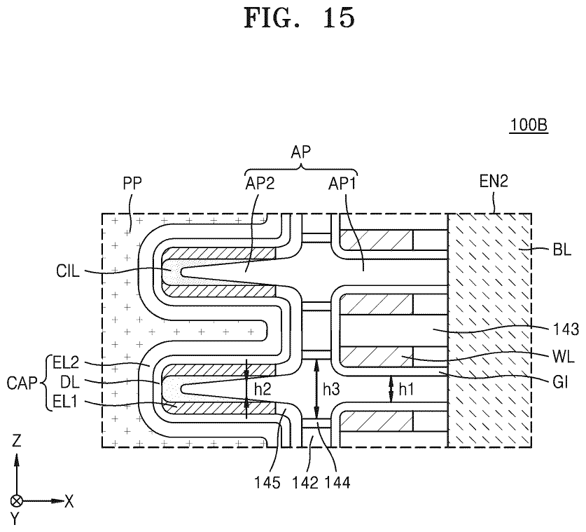

FIG. 15 is a cross-sectional view of a semiconductor memory device 100B according to embodiments.

Referring to FIG. 15, the first part AP1 of each of a plurality of semiconductor patterns AP may have a variable height in the vertical direction Z. For example, a portion of the first part AP1 of each semiconductor pattern AP may be surrounded by a word line WL and may have the first height h1, and a portion of the first part AP1 of the semiconductor pattern AP may be surrounded by the second spacer 142 and the first insulating liner 144 and may have a third height h3 that is greater than the first height h1. The second part AP2 of the semiconductor pattern AP may have the second height h2 in the vertical direction. The second height h2 may be less than either the first height h1 or the third height h3.

In some embodiments, the second part AP2 of the semiconductor pattern AP may have a tapered shape. For example, the width and the height of the second part AP2 of the semiconductor pattern AP may decrease toward the cell capacitor CAP. The first part AP1 of the semiconductor pattern AP may have a tapered shape. For example, the width and the height of the first part AP1 of the semiconductor pattern AP may decrease toward the word line WL.

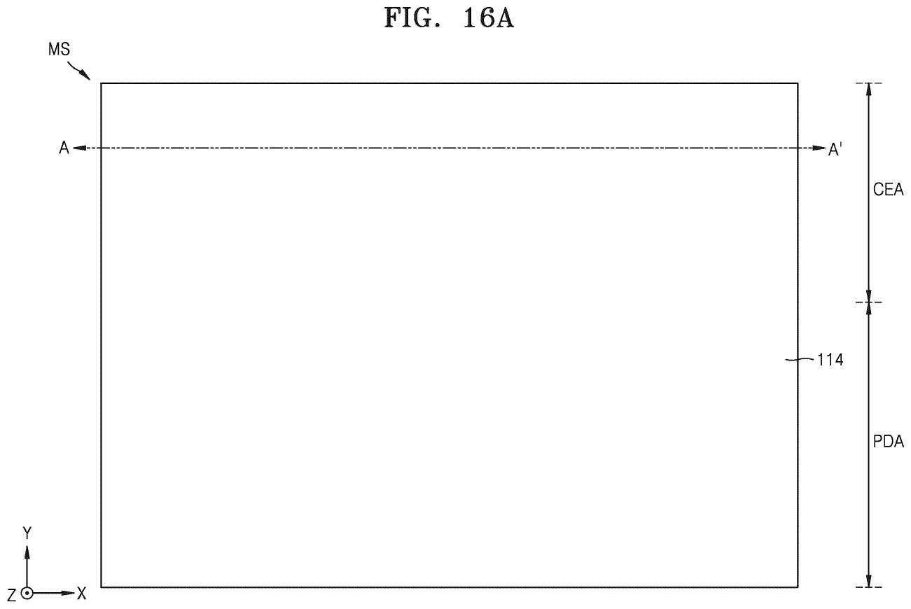

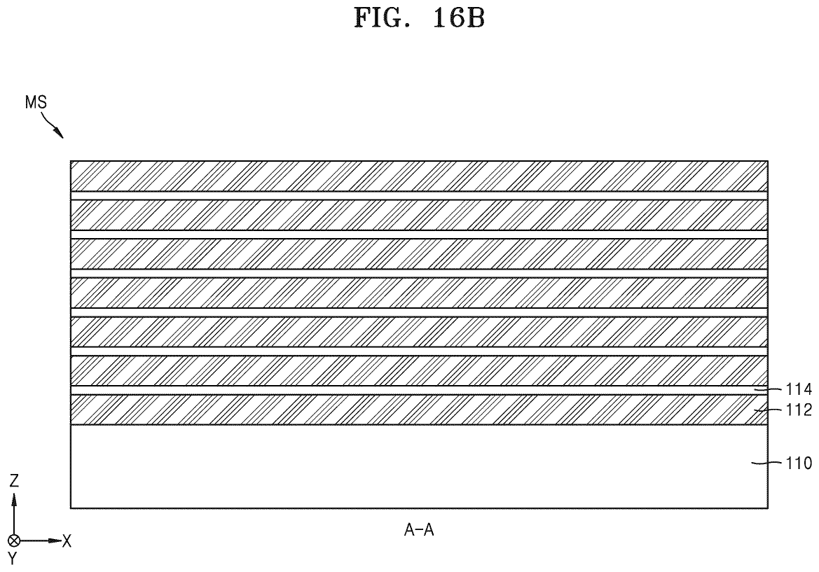

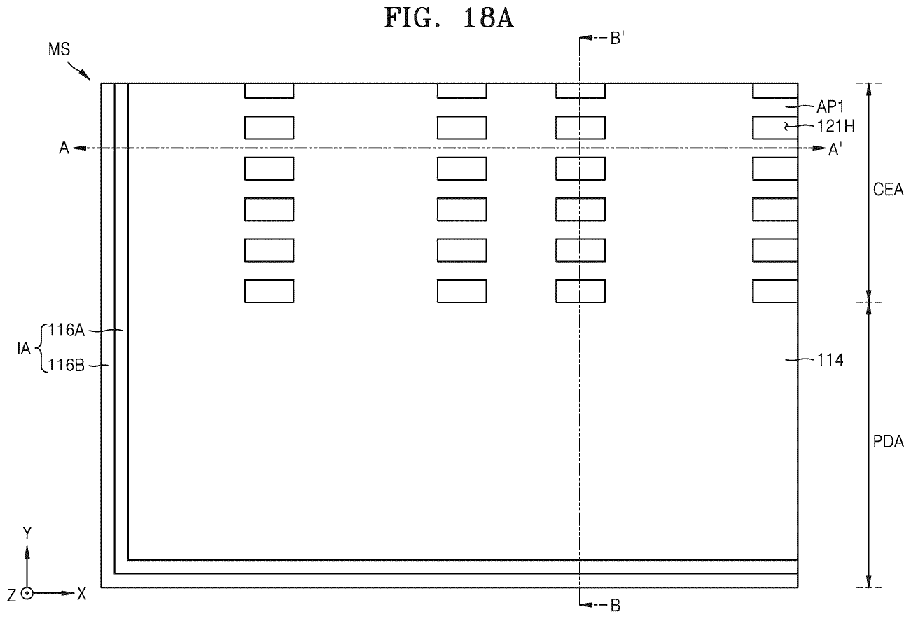

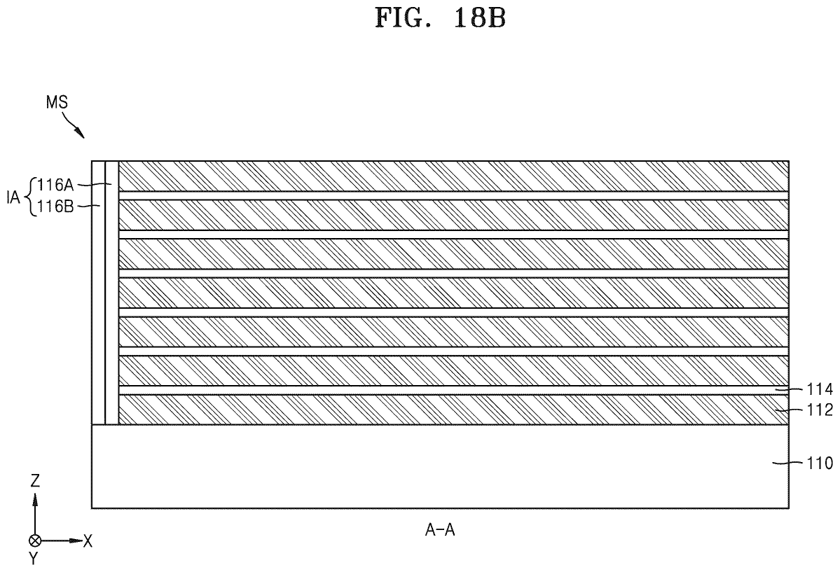

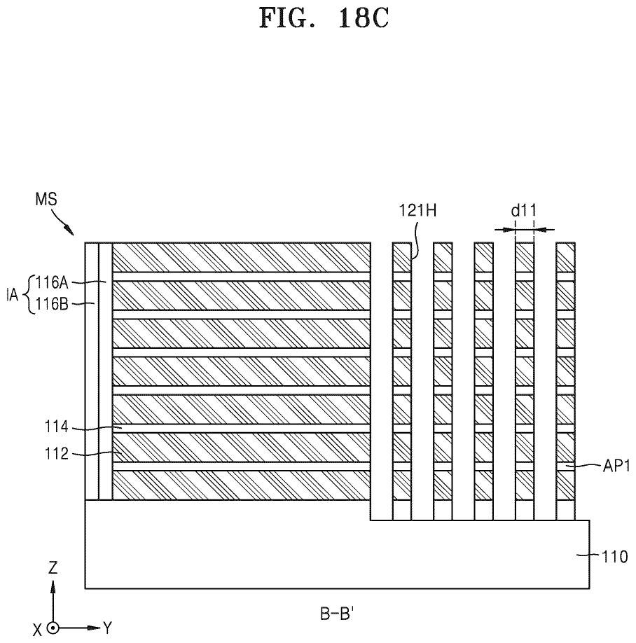

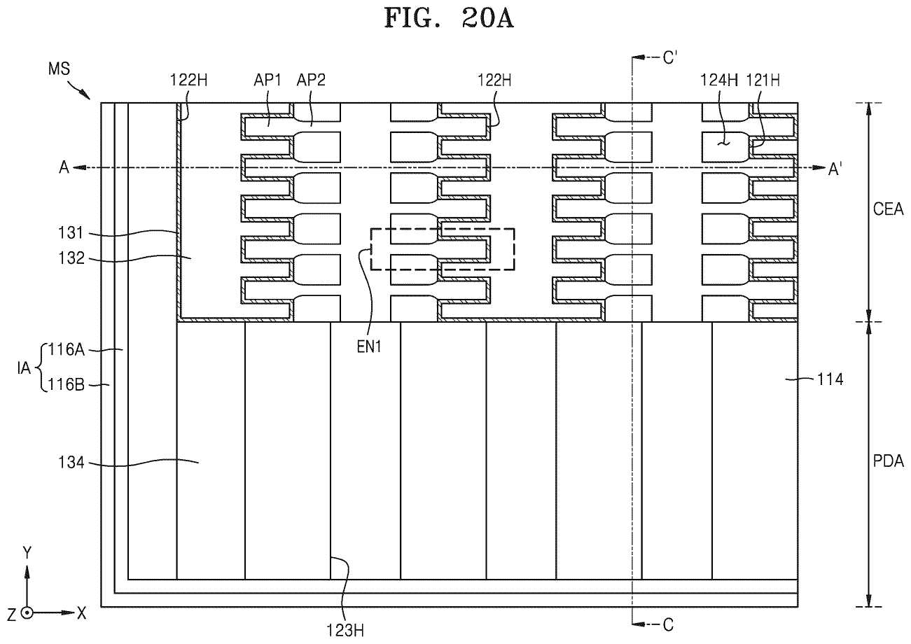

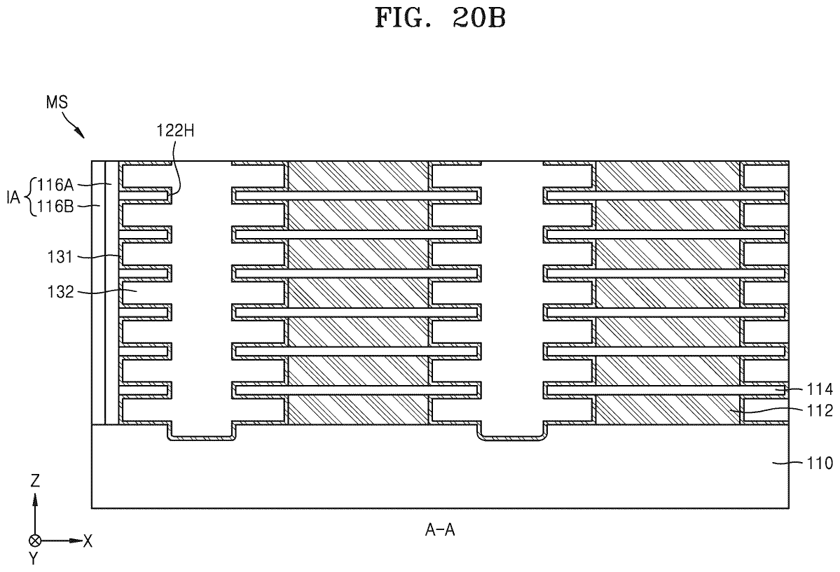

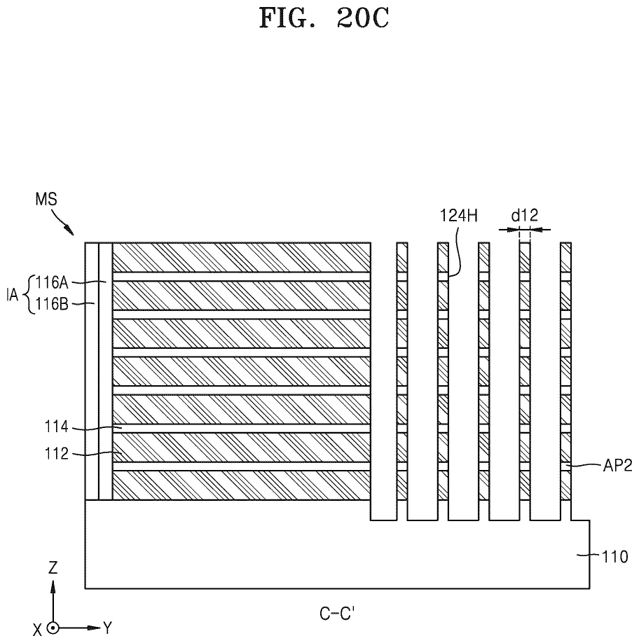

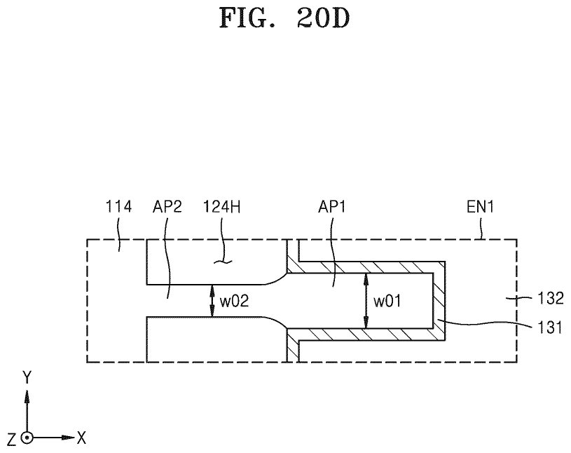

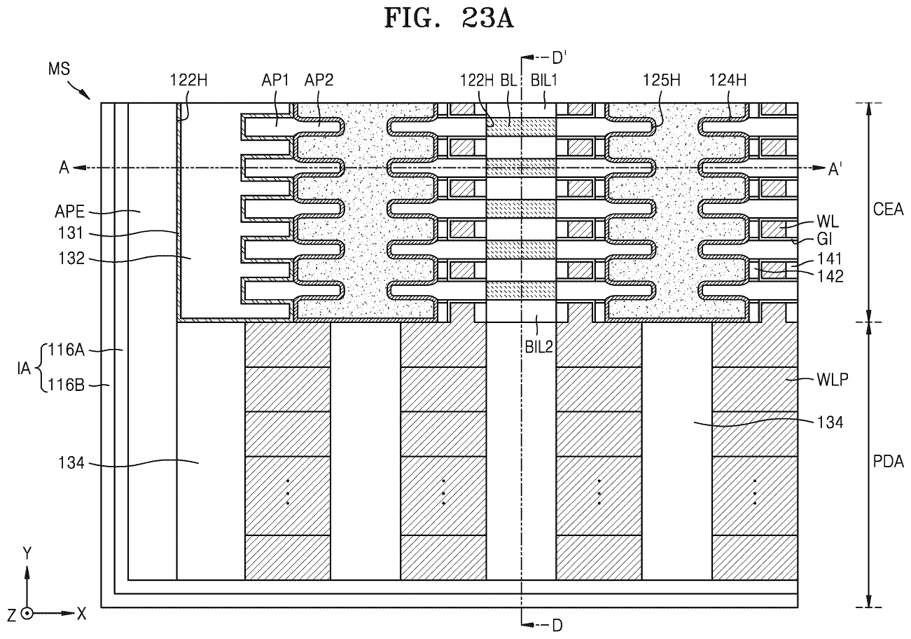

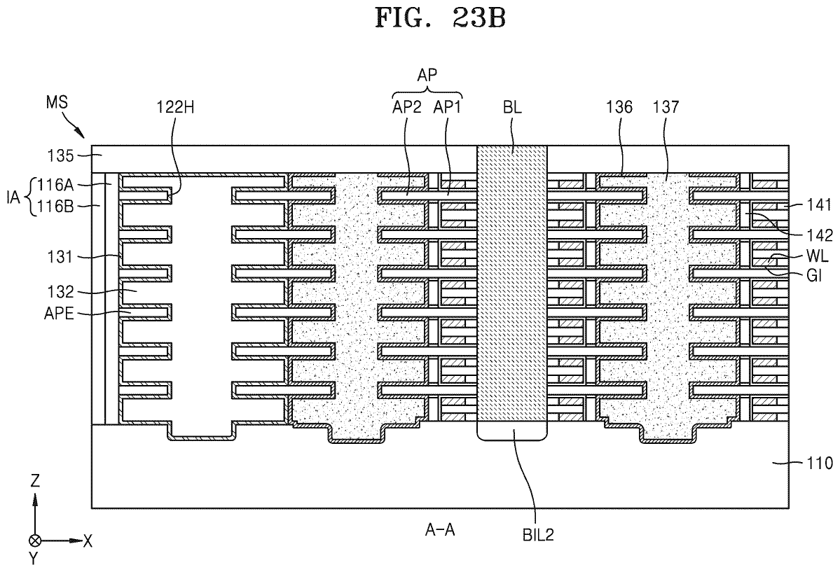

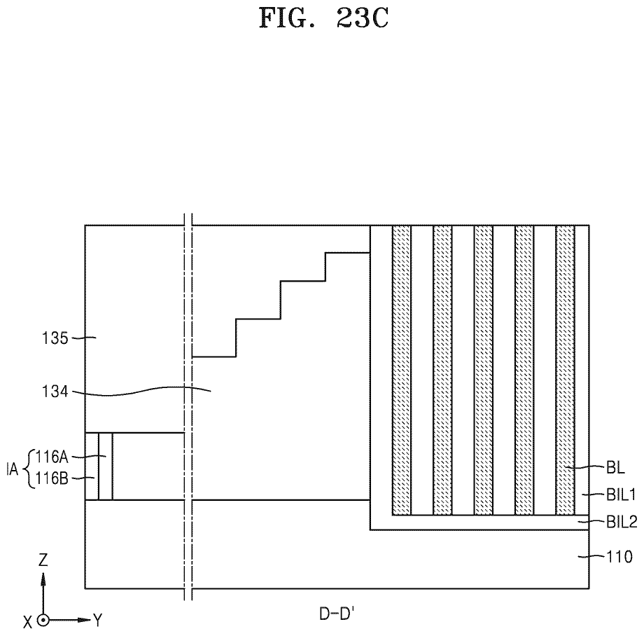

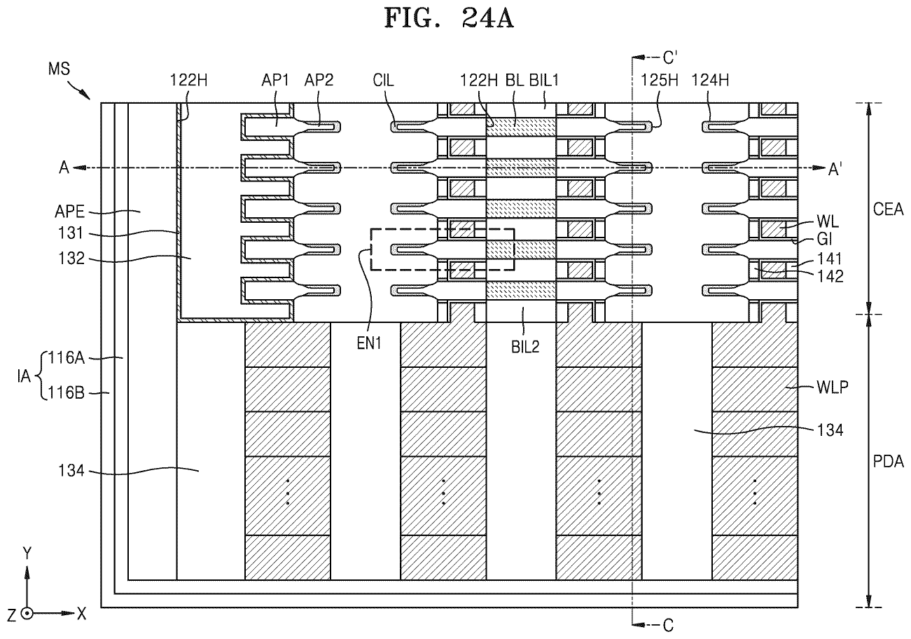

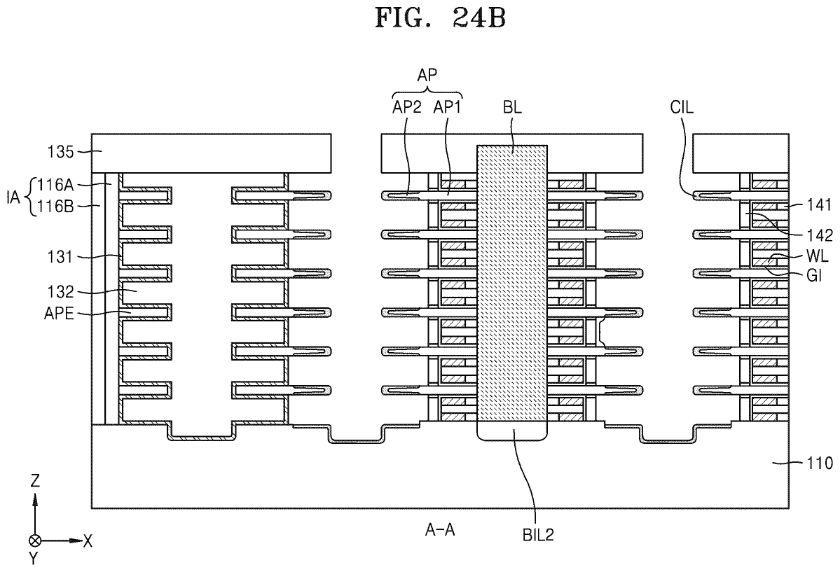

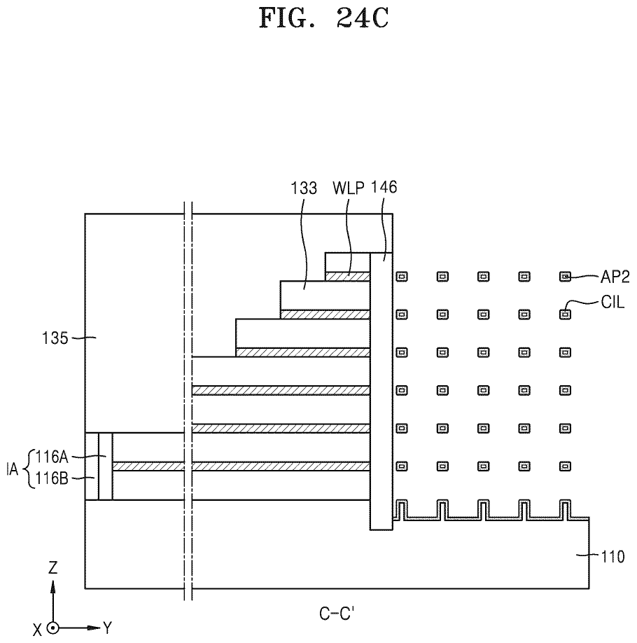

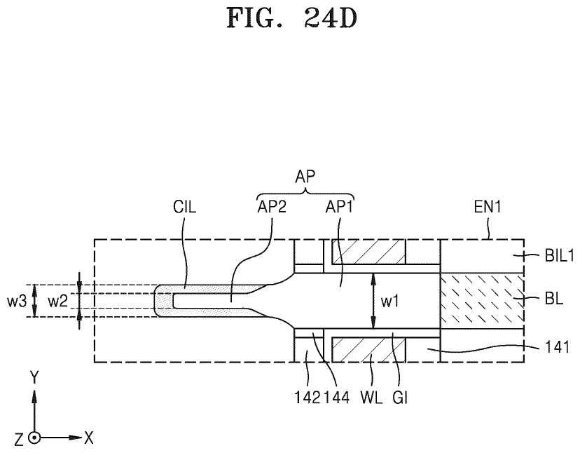

FIGS. 16A, 16B, 17A, 17B, 18A, 18B, 18C, 19A, 19B, 20A, 20B, 20C, 20D, 21A, 21B, 21C, 22A, 22B, 22C, 23A, 23B, 23C, 24A, 24B, 24C, 24D, 25A, 25B, and 25C are schematic diagrams illustrating a method of manufacturing the semiconductor memory device 100. In detail, FIGS. 16A, 17A, 18A, 19A, 20A, 21A, 22A, 23A, 24A, and 25A are plan views of sequential stages in the method. FIGS. 16B, 17B, 18B, 19B, 20B, 21B, 22B, 23B, 24B, and 25B are cross-sectionals views taken along line A-A in FIGS. 16A, 17A, 18A, 19A, 20A, 21A, 22A, 23A, 24A, and 25A, respectively. FIGS. 18C, 19C, and 22C are cross-sectional views taken along line B-B in FIGS. 18A, 19A, and 22A, respectively. FIGS. 20C, 21C, 24C, and 25C are cross-sectional views taken along line C-C in FIGS. 20A, 21A, 24A, and 25A, respectively. FIG. 23C is a cross-sectional view taken along line D-D in FIG. 23A. FIGS. 20D and 24D are enlarged views of a region EN1 in FIGS. 20A and 24A, respectively.

Referring to FIGS. 16A and 16B, a mold stack MS may be formed by sequentially and alternately forming sacrificial mold layers 112 and semiconductor layers 114 on the first substrate 110.

In some embodiments, the sacrificial mold layers 112 may include a material having an etch selectivity with respect to a material of the semiconductor layers 114. For example, the sacrificial mold layers 112 and the semiconductor layers 114 each may include a monocrystalline layer of a Group IV semiconductor, a Group IV-IV compound semiconductor, a Group III-V compound semiconductor, and/or the like. The sacrificial mold layers 112 may include a material different from the material of the semiconductor layers 114. For example, the sacrificial mold layers 112 may include SiGe and the semiconductor layers 114 may include monocrystalline silicon. The sacrificial mold layers 112 and the semiconductor layers 114 each may have a thickness of several tens of nm.

In some embodiments, the sacrificial mold layers 112 and the semiconductor layers 114 may be formed by an epitaxy process. For example, the epitaxy process may include vapor-phase epitaxy (VPE), a chemical vapor deposition (CVD) process such as ultra-high vacuum (UHV)-CVD, molecular beam epitaxy, or a combination thereof. In the epitaxy process, a liquid or gaseous precursor may be used to form the sacrificial mold layers 112 and the semiconductor layers 114.

In some embodiments, the thickness of the semiconductor layers 114 in the vertical direction Z may be less than the thickness of the sacrificial mold layers 112 in the vertical direction Z, as shown in FIG. 16B. In some embodiments, the thickness of the semiconductor layers 114 in the vertical direction Z may be substantially the same as the height (e.g., h1) of the first part AP1 (see FIG. 10) of a semiconductor pattern AP to be formed in a subsequent process.

In some embodiments, unlike FIG. 16B, the thickness of the semiconductor layers 114 in the vertical direction Z may be greater than the thickness of the sacrificial mold layers 112 in the vertical direction Z. In this case, the thickness of the semiconductor layers 114 in the vertical direction Z may be substantially the same as the height (e.g., h3) of a portion (e.g., a portion surrounded by the second spacer 142 and the first insulating liner 144) of the first part AP1 (see FIG. 15) of the semiconductor pattern AP to be formed in a subsequent process.

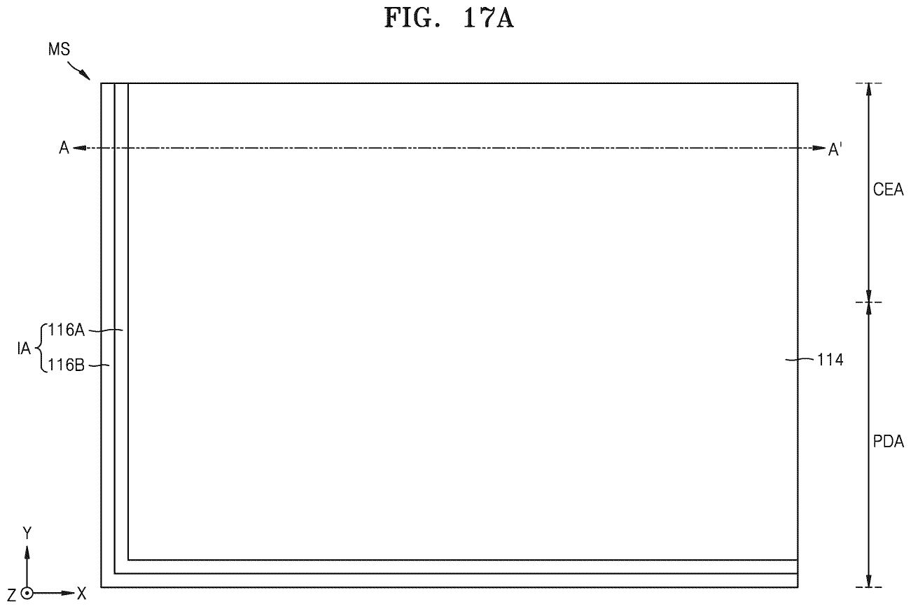

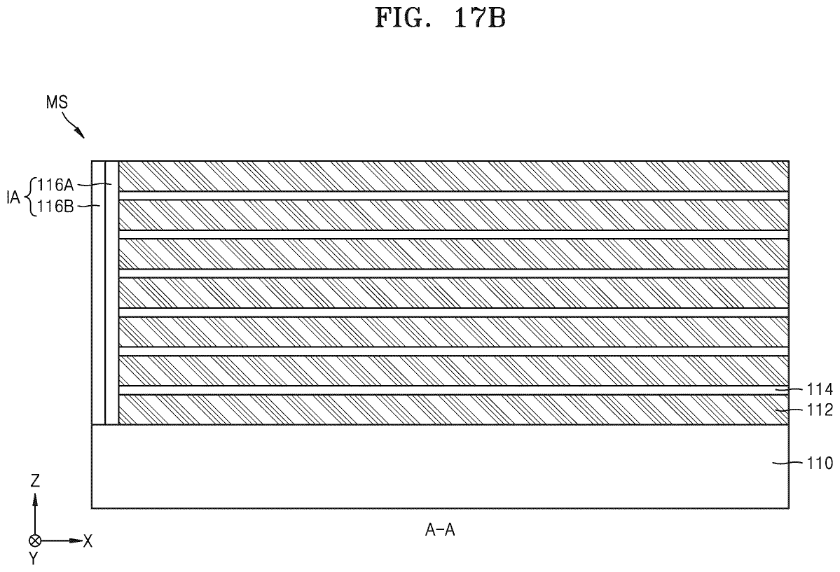

Referring to FIGS. 17A and 17B, a mask pattern (not shown) may be formed on the mold stack MS. A portion of the edge of the mold stack MS may be removed by using the mask pattern as an etch mask. The first device isolation layer 116A and the second device isolation layer 116B may be sequentially formed in the portion of the edge of the mold stack MS. The first device isolation layer 116A and the second device isolation layer 116B may be referred to as the device isolation region IA.

Referring to FIGS. 18A to 18C, a mask pattern (not shown) may be formed on the mold stack MS, and first openings 121H may be formed by partially removing the mold stack MS by using the mask pattern as an etch mask. The first openings 121H may be apart from each other by a first distance d11 in the second horizontal direction Y. For example, the first distance d11 may be about 1 nm to about 50 nm.

First parts AP1 of semiconductor patterns may be defined in the semiconductor layers 114 by the first openings 121H. A portion of a semiconductor layer 114 between two adjacent first openings 121H may be referred to as a first part AP1, and opposite sidewalls of the first part AP1 may be exposed by the first openings 121H. The width of the first part AP1 in the second horizontal direction Y may correspond to the first distance d11 between the first openings 121H in the second horizontal direction Y.

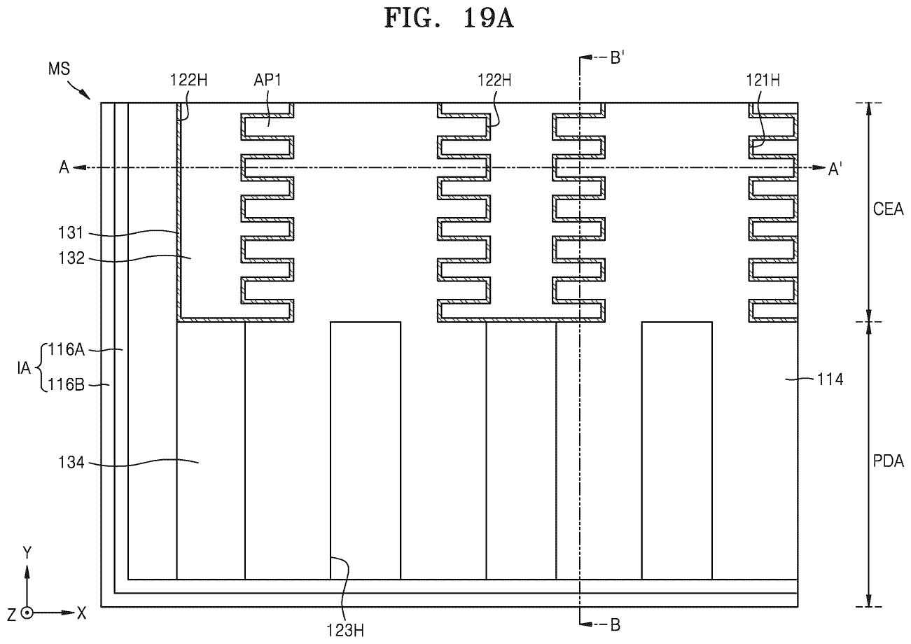

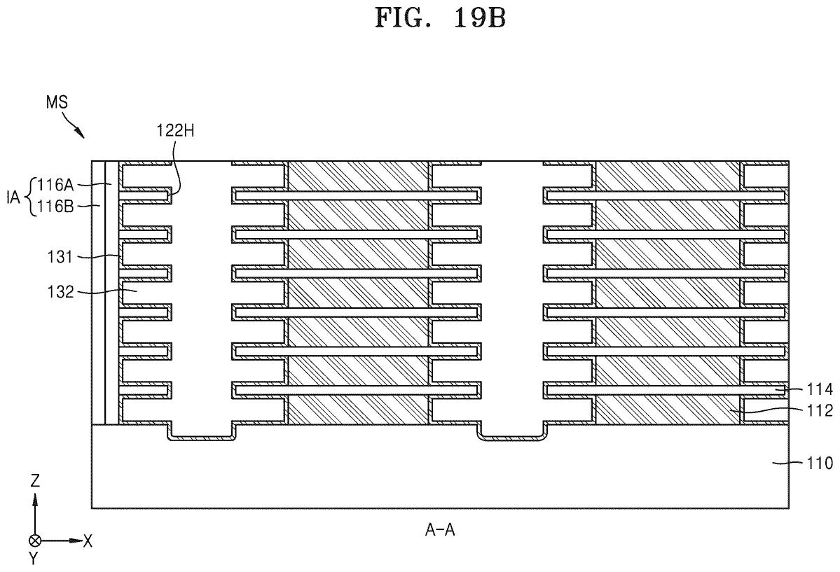

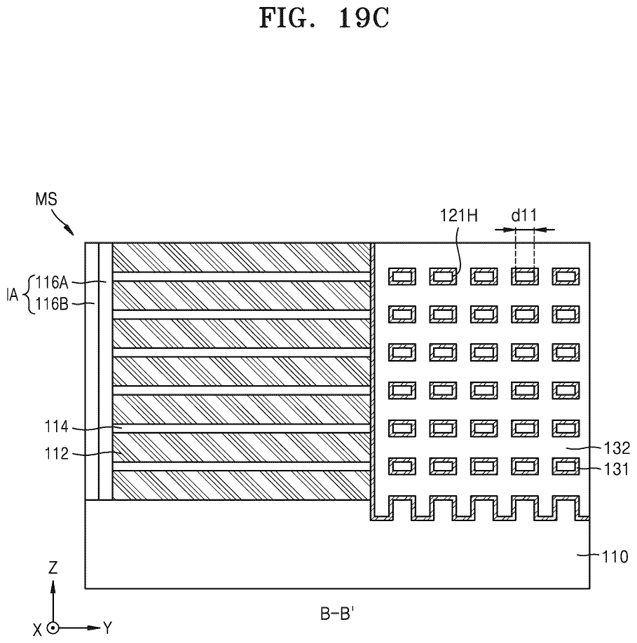

Referring to FIGS. 19A to 19C, a mask pattern (not shown) may be formed on the mold stack MS, and a second opening 122H and a third opening 123H may be formed by partially removing the mold stack MS by using the mask pattern as an etch mask.

In some embodiments, the second opening 122H may extend in the second horizontal direction Y and may be arranged at one side of an end of each of the first openings 121H to communicate with the end of each first opening 121H. The third opening 123H may be arranged in the connection region PDA and may extend in the second horizontal direction Y.

Thereafter, a process of partially removing each of the sacrificial mold layers 112, which are exposed by the first opening 121H, the second opening 122H, and the third opening 123H, may be performed. In some embodiments, the top and bottom surfaces of the first part AP may be exposed by the process.

In some embodiments, the process of partially removing each sacrificial mold layer 112 may include a wet etching process, a pull-back process, and/or the like. For example, the process of partially removing each sacrificial mold layer 112 may include an etching process using an etch selectivity between the sacrificial mold layers 112 and the semiconductor layers 114. For example, in the wet etching process or the pull-back process, an etch rate of the semiconductor layers 114 or the first part AP1 of the semiconductor pattern may be relatively low, and an etch rate of the sacrificial mold layers 112 may be relatively high.

Thereafter, the edge liner 131 and the edge burying layer 132 may be formed in the first opening 121H and the second opening 122H. For example, the edge liner 131 may be conformally formed on the inner wall of the first opening 121H and the second opening 122H, and the edge burying layer 132 may fill the first opening 121H and the second opening 122H. In some embodiments, the edge liner 131 may be conformally formed on the top surface, the bottom surface, and the sidewalls of the first part AP1 in the second opening 122H.

Thereafter, the word line isolation insulating layer 134 may be formed in the third opening 123H.

In some embodiments, the edge liner 131, the edge burying layer 132, and the word line isolation insulating layer 134 may include at least one of silicon oxide, silicon nitride, and/or silicon oxynitride.

Referring to FIGS. 20A to 20D, a mask pattern (not shown) may be formed on the mold stack MS, and fourth openings 124H may be formed by partially removing the mold stack MS by using the mask pattern as an etch mask. The fourth openings 124H may be apart from each other by a second distance d12 in the second horizontal direction Y. For example, the second distance d12 may be about 1 nm to about 30 nm.

Second parts AP2 of semiconductor patterns may be defined in the semiconductor layers 114 by the fourth openings 124H. A portion of a semiconductor layer 114 between two adjacent fourth openings 124H may be referred to as a second part AP2, and opposite sidewalls of the second part AP2 may be exposed by the fourth openings 124H. The width of the second part AP2 in the second horizontal direction Y may correspond to the second distance d12 between the fourth openings 124H in the second horizontal direction Y.

In some embodiments, the second distance d12 between the fourth openings 124H may be less than the first distance d11 (see FIG. 19C) between the first openings 121H. Accordingly, a width w02 of the second part AP2 in the second horizontal direction Y may be less than a width w01 of the first part AP1 in the second horizontal direction Y.

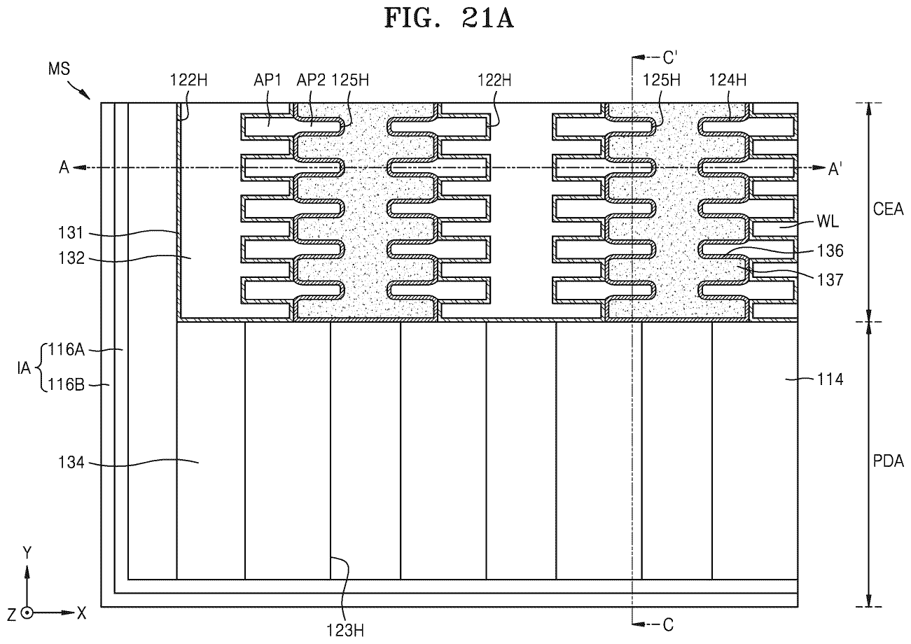

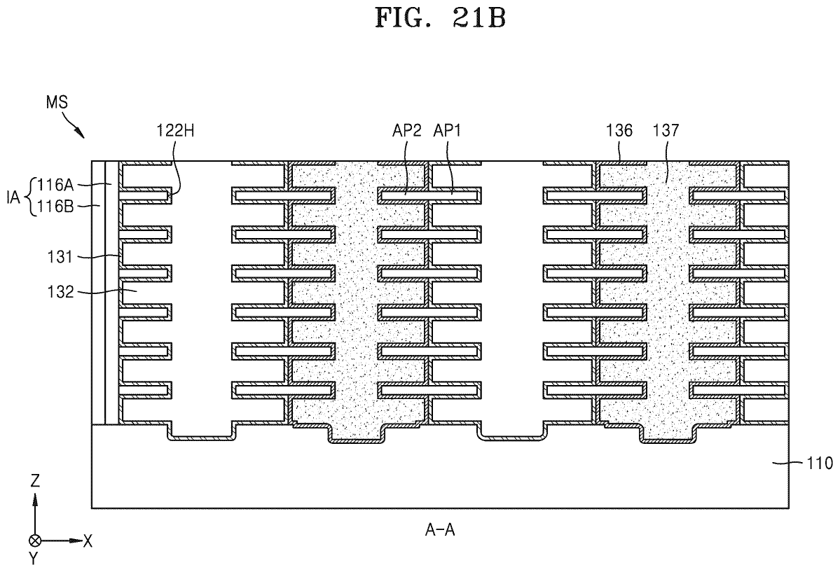

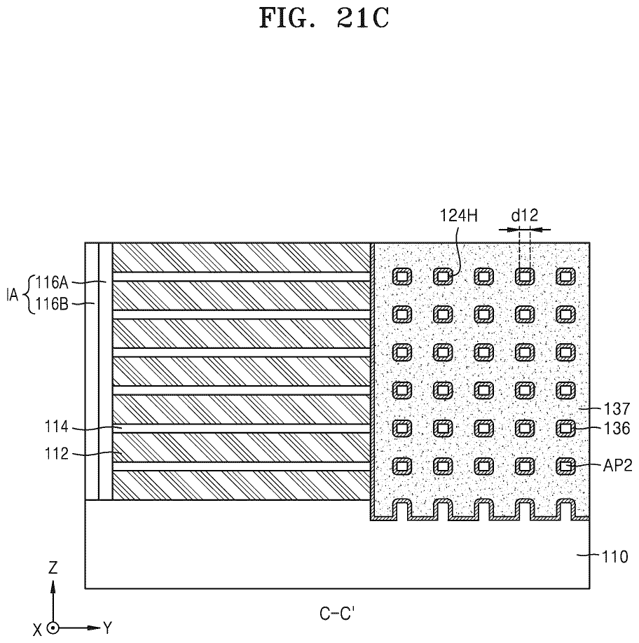

Referring to FIGS. 21A and 21B, a mask pattern (not shown) may be formed on the mold stack MS, and a fifth opening 125H may be formed by partially removing the mold stack MS by using the mask pattern as an etch mask.

In some embodiments, the fifth opening 125H may extend in the second horizontal direction Y and may be arranged at one side of an end of each fourth opening 124H to communicate with the end of the fourth opening 124H.

Thereafter, a process of partially removing each of the sacrificial mold layers 112, which is exposed by the fourth opening 124H and the fifth opening 125H, may be performed. The top and bottom surfaces of the second part AP2 may be exposed by the process.

In some embodiments, the process of partially removing the sacrificial mold layers 112 may include a wet etching process, a pull-back process, and/or the like. For example, the process of partially removing the sacrificial mold layers 112 may include an etching process using an etch selectivity between the sacrificial mold layers 112 and the semiconductor layers 114. For example, in the wet etching process or the pull-back process, an etch rate of the semiconductor layers 114 or the second part AP2 of the semiconductor pattern may be relatively low, and an etch rate of the sacrificial mold layers 112 may be relatively high.

When a sacrificial mold layer 112 is removed from the fourth opening 124H, the surface of the edge liner 131 on the inner wall of the first opening 121H may be exposed in the fourth opening 124H.

Thereafter, a liner 136 and a buried layer 137 may be sequentially formed in the fourth opening 124H and the fifth opening 125H. For example, the liner 136 may be conformally formed on the top and bottom surface of the second part AP2 and the top surface of the first substrate 110, and the buried layer 137 may fill the fifth opening 125H.

In some embodiments, the liner 136 and the buried layer 137 may include at least one of silicon oxide, silicon nitride, and/or silicon oxynitride.

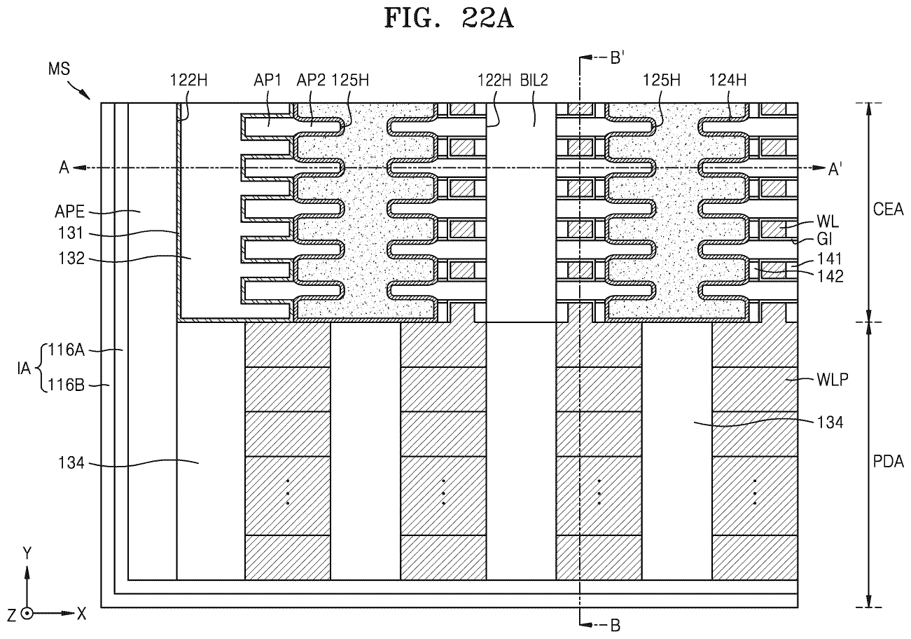

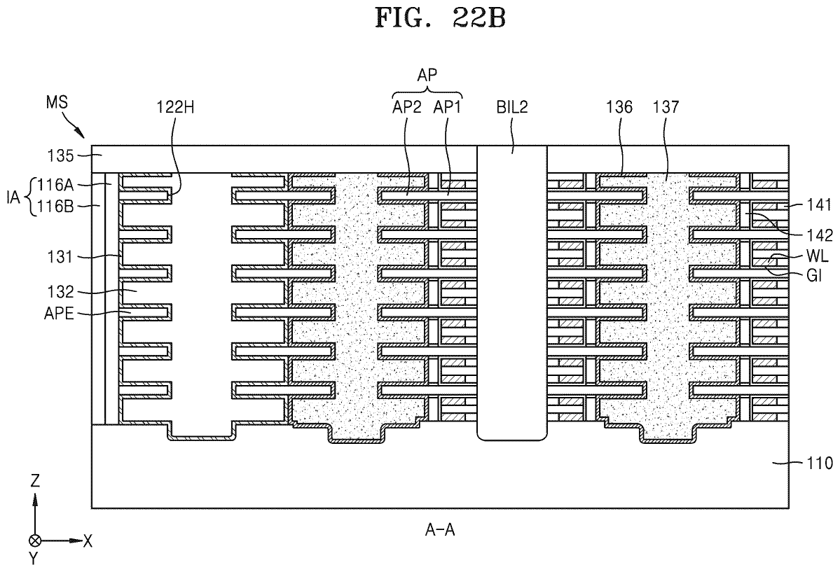

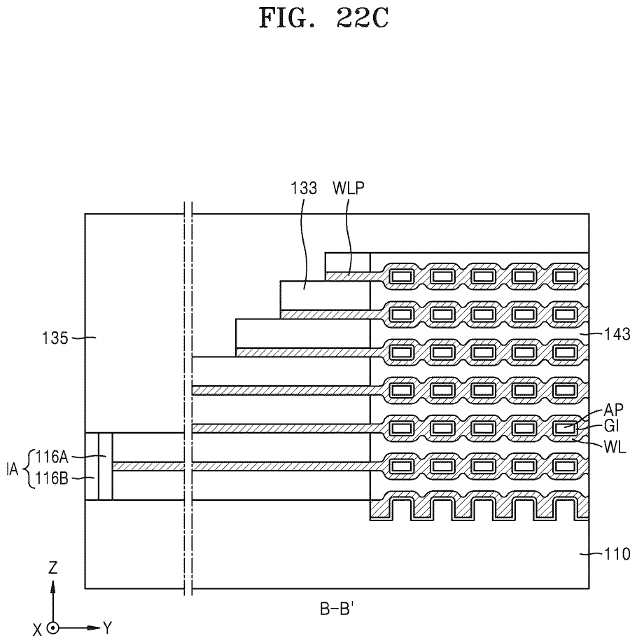

Referring to FIGS. 22A to 22C, the sacrificial mold layers 112 and the semiconductor layers 114 in the connection region PDA may be patterned in a stair shape. The sacrificial mold layers 112 may be removed, and pad insulating layers 133 may be formed at positions where the sacrificial mold layers 112 are removed. Thereafter, the semiconductor layers 114 between the pad insulating layers 133 may be removed to form pad spaces for word line pads.

The edge liner 131 and the edge burying layer 132 may be removed from the first opening 121H and the second opening 122H such that the surface of the first part AP1 of the semiconductor pattern may be exposed. Thereafter, a gate insulating layer GI and a word line WL may be sequentially formed on the exposed surface of the first part AP1.

In some embodiments, before the process of forming the gate insulating layer GI and the word line WL, the first insulating liner 144 and the second spacer 142 may be sequentially formed on the inner wall of the fourth opening 124H to cover at least a portion of the first part AP1 (e.g., an end portion of the first part AP adjacent to the edge liner 131 in the first horizontal direction X). Thereafter, the gate insulating layer GI and the word line WL may be formed on the first insulating liner 144, the second spacer 142, and at least a portion of the first part AP1 (e.g., a central portion of the first part AP1 in the first horizontal direction X).

Thereafter, the first spacer 141 may be formed on the inner wall of the fourth opening 124H to cover at least a portion of the first part AP1 (e.g., an end portion of the first part AP1 far from the edge liner 131 in the first horizontal direction X), and the third spacer 143 may be formed in a space between two adjacent word lines WL in the vertical direction. Thereafter, the second bit line isolation insulating layer BIL2 may be formed in the second opening 122H. The second bit line isolation insulating layer BIL2 may extend in the vertical direction Z and the second horizontal direction Y.

In some embodiments, in a process of forming the word lines WL, the word line pads WLP may be formed in the pad spaces between the pad insulating layers 133 of the connection region PDA. In some embodiments, the word line pads WLP may be formed before or after the word lines WL are formed.

In some embodiments, the word line pads WLP may be arranged in a stepped pattern. For example, a word line pad WLP connected to one word line WL may be apart in the second horizontal direction Y from a word line pad WLP connected to another word line WL below the word line WL.

Referring to FIGS. 23A to 23C, a mask pattern may be formed on the mold stack MS, a portion of the second bit line isolation insulating layer BIL2 may be removed by using the mask pattern as an etch mask, and a bit line BL may be formed in a space where the portion of the second bit line isolation insulating layer BIL2 is removed.

In some embodiments, the bit line BL may be in contact with a sidewall of the first part AP1 of a semiconductor pattern AP. In some embodiments, the sidewall of the first part AP1 of the semiconductor pattern AP may be aligned with a sidewall of the first spacer 141 and/or a sidewall of the third spacer 143, and accordingly, a sidewall of the bit line BL may extend substantially vertically.

In some embodiments, a sidewall of the first part AP1 of the semiconductor pattern AP may protrude outwards (e.g., toward the bit line BL) from a sidewall of the first spacer 141 and/or a sidewall of the third spacer 143, and accordingly, the sidewall of the bit line BL may be recessed inward at a position corresponding to the first part AP1 of the semiconductor pattern AP.

In some embodiments, one bit line BL may be arranged between two first parts AP1 which are apart from each other in the first horizontal direction X, and two transistors formed by these two first parts AP1 may share one bit line BL.

However, in some embodiments, two bit lines BL may be apart from each other in the first horizontal direction X such that one of the bit lines BL may be connected to one first part AP1 and the other bit line BL may be connected to another first part AP1. In these cases, the semiconductor memory device 100A described above with reference to FIG. 14 may be formed.

Referring to FIGS. 24A to 24D, a mask pattern may be formed on the mold stack MS, the liner 136 and the buried layer 137 may be removed from the fourth opening 124H and the fifth opening 125H by using the mask pattern as an etch mask, and the surface of the second part AP2 of the semiconductor pattern AP may be exposed.

Thereafter, the intermediate conductive layer CIL may be formed on the surface of the second part AP2 of the semiconductor pattern AP and the surface of the first substrate 110.

In some embodiments, the intermediate conductive layer CIL may be formed by a silicidation process and may include a metal silicide, such as cobalt silicide, nickel silicide, or tungsten silicide.

For example, the intermediate conductive layer CIL may be selectively formed on the surface of the second part AP2 of the semiconductor pattern AP and the surface of the first substrate 110. In some embodiments, in the silicidation process for the formation of the intermediate conductive layer CIL, a portion of the second part AP2 by a certain depth from the outer surface of the second part AP2 may be converted into the intermediate conductive layer CIL. For example, as shown in FIG. 24D, the surface of the second part AP2 of the semiconductor pattern AP may be covered with the intermediate conductive layer CIL, and the second part AP2 of the semiconductor pattern AP may have a tapered shape toward the fifth opening 125H. In some embodiments, the second width w2 of the second part AP2 of the semiconductor pattern AP in the second horizontal direction Y may be less than the width w02 of the second part AP2 in the second horizontal direction Y in FIG. 20D.

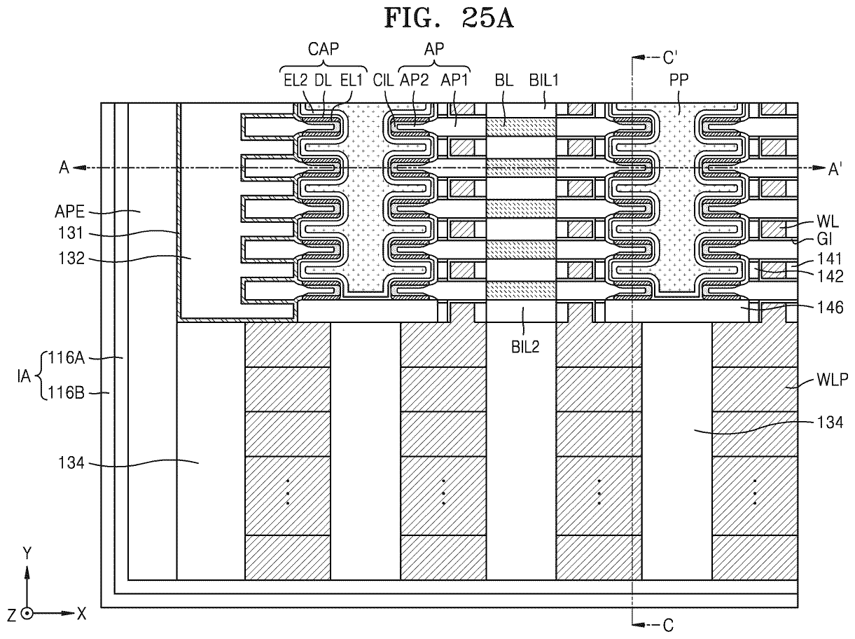

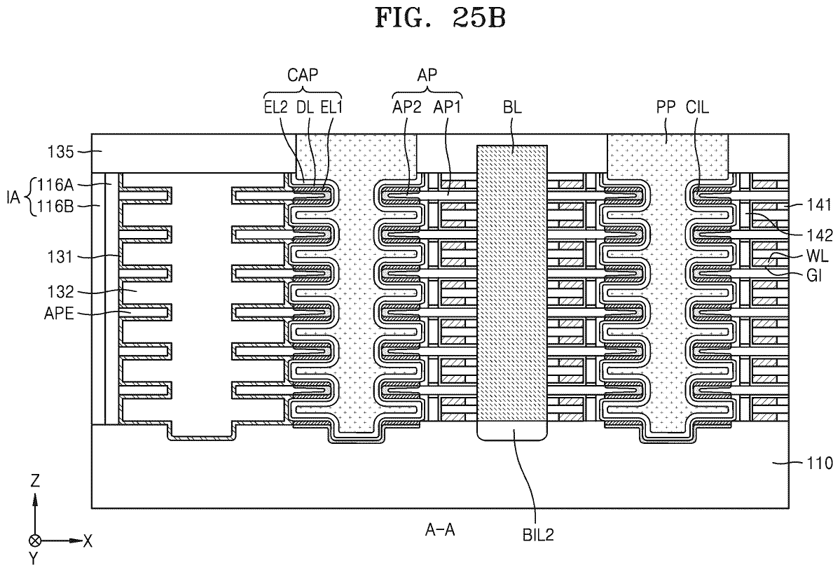

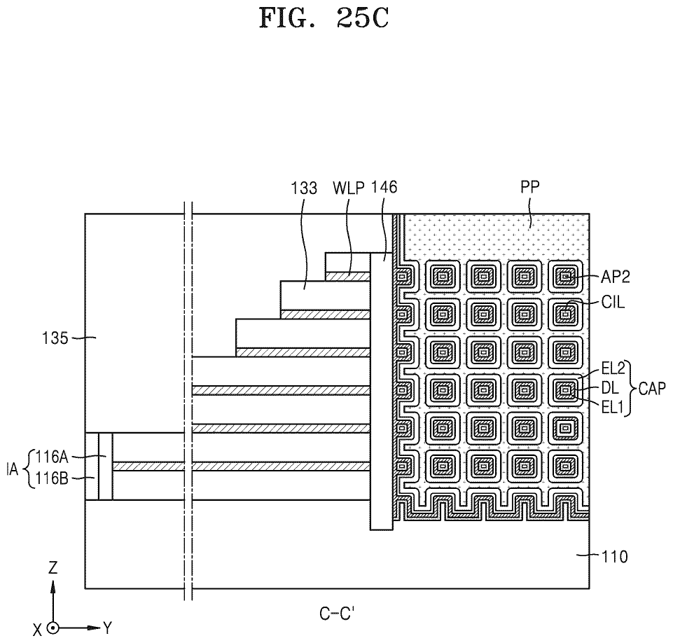

Referring to FIGS. 25A to 25C, a cell capacitor CAP may be formed by sequentially forming a first electrode EL1, a capacitor dielectric layer DL, and a second electrode EL2 on the surface of the intermediate conductive layer CIL in the fourth opening 124H and the fifth opening 125H.

In some embodiments, before the first electrode EL1 is formed, the second insulating liner 145 may be formed on an end portion of the second part AP2 of the semiconductor pattern AP in the first horizontal direction X (e.g., a portion of a sidewall of the second part AP2 of the semiconductor pattern AP, which is adjacent to the second spacer 142). The first electrode EL1 may be formed by forming a conductive layer on the surface of the intermediate conductive layer CIL and performing an etch-back process on the conductive layer.

In some embodiments, a first electrode EL1 surrounding one second part AP2 may not be electrically connected to a first electrode EL1 surrounding another adjacent second part AP2. The second insulating liner 145 may be arranged between an end portion of the first electrode EL1 surrounding one second part AP2 and an end portion of the first electrode EL1 surrounding the adjacent second part AP2.

In some embodiments, in the etch-back process, a portion of the conductive layer, which is arranged on a sidewall of an end portion of the intermediate conductive layer CIL arranged inward in the fifth opening 125H, may also be removed such that the sidewall of the end portion of the intermediate conductive layer CIL may not be covered with the first electrode EL1 but be exposed. However, in some embodiments, in the etch-back process, a portion of the conductive layer, which is arranged on a sidewall of an end portion of the intermediate conductive layer CIL arranged inward in the fifth opening 125H, may not be completely removed such that the sidewall of the end portion of the intermediate conductive layer CIL may be covered with the first electrode EL1.

In some embodiments, the capacitor dielectric layer DL may be arranged on the first electrode EL1. For example, the capacitor dielectric layer DL may be conformally arranged on the top surface, the bottom surface, and the sidewall of the first electrode EL1. The second electrode EL2 may be arranged on the capacitor dielectric layer DL. The second electrode EL2 may be conformally arranged on the top surface, the bottom surface, and the sidewall of the capacitor dielectric layer DL.

In some embodiments, the second part AP2 of the semiconductor pattern AP may have the second width w2 (see FIG. 24D) (for example, the second width w2 that is less than the first width w1 of the first part AP1 of the semiconductor pattern AP). Respective second parts AP2 of two adjacent semiconductor patterns AP may be apart from each other by a relatively large distance in the second horizontal direction Y. Accordingly, the gap between two adjacent second parts AP2 may be secured relatively large, and thus, the first electrode EL1, the capacitor dielectric layer DL, and the second electrode EL2 may be conformally formed between two adjacent second parts AP2.

Thereafter, a plate electrode PP may be formed on the cell capacitor (for example, on the surface of the second electrode EL2). In some embodiments, as shown in FIG. 25C, at least a portion of the plate electrode PP may fill a space between two adjacent cell capacitors CAP (for example, a space between two adjacent cell capacitors CAP in the second horizontal direction Y and/or a space between two adjacent cell capacitors CAP in the vertical direction).

Referring back to FIG. 13, the upper wiring structure 150 may be formed on the cell capacitor CAP and the cover insulating layer 135. The upper wiring structure 150 may include the wiring layer 152, the via 154, the insulating layer 156, and the contact 158. For example, the contact 158 may be electrically connected to the bit line BL, the word line WL, and the plate electrode PP. Thereafter, the first bonding pad BP1 may be formed on the same plane as the topmost surface of the insulating layer 156 of the upper wiring structure 150.

Thereafter, the peripheral circuit region PCA may be prepared.

In some embodiments, the peripheral circuit region PCA may include the second substrate, the peripheral circuit transistor 220 on the substrate 210, the front wiring structure 230 on the substrate 210, and the back wiring structure 240 on the bottom surface of the substrate 210. The front wiring structure 230 may cover the peripheral circuit transistor 220.

In some embodiments, the peripheral circuit transistor 220 may be formed on a first surface (or the top surface) of the substrate 210, the front wiring structure 230 may be formed on the first surface of the substrate 210, a carrier substrate may be attached to the front wiring structure 230, and then the substrate 210 may be thinned by grinding a second surface (or the bottom surface) of the substrate 210. Thereafter, the peripheral circuit region PCA may be completely formed by forming the back wiring structure 240 and the second bonding pad BP2 on the second surface of the substrate 210.

Thereafter, the peripheral circuit region PCA may be bonded to the cell array region MCA. At this time, the first bonding pad BP1 of the cell array region MCA may be bonded to the second bonding pad BP2 of the peripheral circuit region PCA, and the top surface of the insulating layer 156 of the upper wiring structure 150 may be bonded to the bottom surface of the insulating layer 246 of the back wiring structure 240.

According to the method of manufacturing the semiconductor memory device 100, according to the embodiments described above, a first part AP1 of a semiconductor pattern AP may be patterned first, and then, a second part AP2 of the semiconductor pattern AP may be patterned. Accordingly, the performance of a cell transistor may be improved and/or optimized by forming a word line WL (and the like) around the first part AP1 having a relatively large width, and a process defect, such as a filling defect, may be prevented from occurring in a process of forming a cell capacitor CAP around the second part AP2 having a relatively small width.

For a semiconductor memory device of the inventive concepts, a first part of a semiconductor pattern may be patterned first, and then, a second part of the semiconductor pattern may be patterned. Accordingly, the performance of a cell transistor may be improved and/or optimized by forming a word line and the like around the first part having a relatively large width, and a process defect, such as a filling defect, may be prevented from occurring in a process of forming a cell capacitor around the second part having a relatively small width.

While the inventive concepts have been particularly shown and described with reference to embodiments thereof, it will be understood that various changes in form and details may be made therein without departing from the spirit and scope of the following claims.

What is claimed is:

1. A semiconductor memory device comprising:
a plurality of semiconductor patterns extending in a first horizontal direction on a substrate, the plurality of semiconductor patterns spaced apart from each other in a vertical direction and a second horizontal direction crossing the first horizontal direction, the plurality of semiconductor patterns each including a first part having a first width in the second horizontal direction and a second part having a second width in the second horizontal direction, the second width being less than the first width;
a plurality of word lines extending in the second horizontal direction, the plurality of word lines each surrounding the first part of a corresponding semiconductor pattern of the plurality of semiconductor patterns; and
a plurality of cell capacitors each surrounding the second part of a corresponding semiconductor pattern of the plurality of semiconductor patterns.

2. The semiconductor memory device of claim 1, further comprising:
a plurality of intermediate conductive layers, each of the plurality of intermediate conductive layers on a top surface and a bottom surface of the second part of a corresponding one of the plurality of semiconductor patterns,
the plurality of intermediate conductive layers comprising a metal silicide.

3. The semiconductor memory device of claim 2, wherein
the plurality of intermediate conductive layers have a third width in the second horizontal direction, and
the third width is less than the first width of the first part of the corresponding one of the plurality of semiconductor pattern.

4. The semiconductor memory device of claim 2, further comprising:
a plate electrode on the substrate and extending in the vertical direction, the plate electrode connected to the plurality of cell capacitors; and
a plurality of bit lines extending in the vertical direction, each of the plurality of bit lines connected to an end of the first part of each of the plurality of semiconductor patterns and.

5. The semiconductor memory device of claim 4, wherein each of the plurality of cell capacitors includes
a first electrode surrounding a top surface, a bottom surface, and a sidewall of one of the plurality of intermediate conductive layers;
a capacitor dielectric layer surrounding a top surface, a bottom surface, and a sidewall of the first electrode; and
a second electrode surrounding a top surface, a bottom surface, and a sidewall of the capacitor dielectric layer.

6. The semiconductor memory device of claim 5, wherein the plurality of cell capacitors include
a first cell capacitor at a first vertical level; and
a second cell capacitor at the first vertical level and adjacent to the first cell capacitor, and
wherein a portion of the plate electrode is between the first cell capacitor and the second cell capacitor.

7. The semiconductor memory device of claim 5, wherein the plurality of cell capacitors include
a first cell capacitor at a first vertical level and
a second cell capacitor at a second vertical level lower than the first vertical level, the second cell capacitor adjacent to the first cell capacitor, and
wherein a portion of the plate electrode is between the first cell capacitor and the second cell capacitor.

8. The semiconductor memory device of claim 4, wherein
the second width of the second part of each of the plurality of semiconductor patterns decreases towards the plate electrode.

9. The semiconductor memory device of claim 1, wherein
the first part of each of the plurality of semiconductor patterns has a first thickness in the vertical direction, and
the second part of each of the plurality of semiconductor patterns has a second thickness,
wherein the second thickness is less than the first thickness in the vertical direction.

10. The semiconductor memory device of claim 1, wherein the plurality of word lines each include:
a first word line surrounding a first semiconductor pattern of the plurality of semiconductor patterns, the first semiconductor pattern at a first vertical level; and
a second word line surrounding a second semiconductor pattern of the plurality of semiconductor patterns, the second semiconductor pattern at a second vertical level lower than the first vertical level,
wherein the semiconductor memory device further comprises:
a first word line pad at the first vertical level and connected to the first word line; and
a second word line pad at the second vertical level, connected to the second word line, and not vertically overlapping the first word line pad.

11. A semiconductor memory device comprising:
a plurality of semiconductor patterns extending in a first horizontal direction on a substrate, the plurality of semiconductor patterns spaced apart from each other in a vertical direction and a second horizontal direction crossing the first horizontal direction, the plurality of semiconductor patterns each including a first part having a first width in the second horizontal direction and a second part having a second width in the second horizontal direction, the second width being less than the first width;
a plurality of word lines extending in the second horizontal direction, the plurality of word lines each surrounding the first part of a corresponding semiconductor pattern of the plurality of semiconductor patterns;
a plurality of cell capacitors each surrounding the second part of a corresponding semiconductor pattern of the plurality of semiconductor patterns; and
a plate electrode extending in the vertical direction on the substrate, the plate electrode connected to the plurality of cell capacitors,
wherein the second width of the second part of each of the plurality of semiconductor patterns decreases towards the plate electrode.

12. The semiconductor memory device of claim 11, further comprising:
a plurality of intermediate conductive layers, each of the plurality of intermediate conductive layers on a top surface and a bottom surface of the second part of a corresponding one of the plurality of semiconductor patterns, the plurality of intermediate conductive layers comprising a metal silicide; and
a plurality of bit lines extending in the vertical direction, each of the plurality of bit lines connected to an end of the first part of each of the plurality of semiconductor patterns.

13. The semiconductor memory device of claim 12, wherein
the plurality of intermediate conductive layers have a third width in the second horizontal direction, and
the third width is less than the first width of the first part of each of the plurality of semiconductor patterns.

14. The semiconductor memory device of claim 12, wherein each of the plurality of cell capacitors includes
a first electrode surrounding a top surface, a bottom surface, and a sidewall of one of the plurality of intermediate conductive layers;
a capacitor dielectric layer surrounding a top surface, a bottom surface, and a sidewall of the first electrode; and
a second electrode surrounding a top surface, a bottom surface, and a sidewall of the capacitor dielectric layer.

15. The semiconductor memory device of claim 12, wherein the plurality of cell capacitors include
first cell capacitor arranged at a first vertical level; and
a second cell capacitor at the first vertical level and adjacent to the first cell capacitor, and
wherein a portion of the plate electrode is between the first cell capacitor and the second cell capacitor.

16. The semiconductor memory device of claim 12, wherein the plurality of cell capacitors include
a first cell capacitor at a first vertical level; and
a second cell capacitor at a second vertical level lower than the first vertical level, the second cell capacitor adjacent to the first cell capacitor, and
wherein a portion of the plate electrode is between the first cell capacitor and the second cell capacitor.

17. The semiconductor memory device of claim 12, wherein
the first part of each of the plurality of semiconductor patterns has a first thickness in the vertical direction, and
the second part of each of the plurality of semiconductor patterns has a second thickness in the vertical direction,
wherein second thickness is less than the first thickness.

18. A semiconductor memory device comprising:
a peripheral circuit region at a first vertical level; and
a cell array region at a second vertical level different from the first vertical level,
wherein the cell array region includes
a plurality of semiconductor patterns extending in a first horizontal direction on a substrate, the plurality of semiconductor patterns spaced apart from each other in a vertical direction and a second horizontal direction crossing the first horizontal direction, the plurality of semiconductor patterns each including a first part having a first width in the second horizontal direction and a second part having a second width in the second horizontal direction, the second width being less than the first width;
a plurality of word lines extending in the second horizontal direction, the plurality of word lines each surrounding the first part of a corresponding semiconductor pattern of the plurality of semiconductor patterns;
a plurality of cell capacitors each surrounding the second part of a corresponding semiconductor pattern of the plurality of semiconductor patterns;
a plurality of intermediate conductive layers, each of the plurality of intermediate conductive layers on a top surface of and a bottom surface of the second part of a corresponding semiconductor pattern of the plurality of semiconductor patterns, the plurality of intermediate conductive layers comprising a metal silicide;
a plate electrode extending in the vertical direction on the substrate and connected to the plurality of cell capacitors; and
a plurality of bit lines extending in the vertical direction, each of the plurality of bit lines connected to an end of the first part of each of the plurality of semiconductor patterns.

19. The semiconductor memory device of claim 18, wherein each of the plurality of cell capacitors includes
a first electrode surrounding a top surface, a bottom surface, and a sidewall of one of the plurality of intermediate conductive layers;
a capacitor dielectric layer surrounding a top surface, a bottom surface, and a sidewall of the first electrode; and
a second electrode surrounding a top surface, a bottom surface, and a sidewall of the capacitor dielectric layer,
wherein a portion of the plate electrode is between two cell capacitors adjacent to each other in the vertical direction, and
wherein another portion of the plate electrode is between two cell capacitors adjacent to each other in the second horizontal direction.

20. The semiconductor memory device of claim 18, wherein
the first part of each of the plurality of semiconductor patterns has a first thickness in the vertical direction, and
the second part of each of the plurality of semiconductor patterns has a second thickness in the vertical direction, and
wherein the second thickness is less than the first thickness.
